(19) United States
(12) Patent Application Publication
(10) Pub. No.: US 2025/0393365 A1
(43) Pub. Date: Dec. 25, 2025

(54) DISPLAY DEVICE, METHOD OF MANUFACTURING DISPLAY DEVICE AND ELECTRONIC DEVICE INCLUDING DISPLAY DEVICE

(71) Applicant: Samsung Display Co., LTD., Yongin-si (KR)

(72) Inventors: Jong Duk ROH, Yongin-si (KR); Yoon Ho LEE, Yongin-si (KR); Jeong Hyun JO, Yongin-si (KR)

(21) Appl. No.: 19/202,080

(22) Filed: May 8, 2025

(30) Foreign Application Priority Data
Jun. 21, 2024 (KR) 10-2024-0080918
Jul. 12, 2024 (KR) 10-2024-0092675

(51) Int. Cl. H10H 29/49; H10H 29/01

(52) U.S. Cl. CPC H10H 29/49; H10H 29/012

(57) ABSTRACT

A display device is provided including a substrate; a pixel circuit layer disposed on the substrate; a first electrode formed on the pixel circuit layer; a second electrode formed on the pixel circuit layer and spaced apart from the first electrode; and a light emitting element connected to the first electrode and the second electrode through a conductive material. An overflow prevention pattern formed on at least one of the first electrode and the second electrode is configured to prevent an overflow of the conductive material or control a direction of the overflow of the conductive material.

This application claims priority to Korean Patent Application No. 10-2024-0080918, filed on Jun. 21, 2024, and Korean Patent Application No. 10-2024-0092675, filed on Jul. 12, 2024, and all the benefits accruing therefrom under 35 U.S.C. § 119, the contents of which in their entirety are herein incorporated by reference.

### BACKGROUND OF THE INVENTION

### (a) Field of the Invention

The present disclosure relates to a display device, a method of manufacturing the display device and an electronic device including the display device.

### (b) Description of the Related Art

With the development of information technology, the importance of a display device that is a connecting medium between a user and information is being highlighted. In response to this, the use of display devices, such as a liquid crystal display device, an organic light emitting display device, and a micro light emitting diode display device, is increasing.

During a manufacturing process of a display device, when a defect occurs in a light emitting element, a process of replacing the light emitting element may be performed. In this process, a conductive material in a liquid state is used, and as the conductive material overflows, a short circuit may occur between an anode electrode and a cathode electrode of a light emitting element.

### SUMMARY OF THE INVENTION

A technical object to be achieved is to provide a display device that may prevent a short circuit between an anode electrode and a cathode electrode of a light emitting element, and a method of manufacturing the display device.

An embodiment provides a display device including: a substrate; a pixel circuit layer disposed on the substrate; a first electrode formed on the pixel circuit layer; a second electrode formed on the pixel circuit layer and spaced apart from the first electrode; and a light emitting element connected to the first electrode and the second electrode through a conductive material. An overflow prevention pattern formed on at least one of the first electrode and the second electrode is configured to prevent an overflow of the conductive material or control a direction of the overflow of the conductive material.

In an embodiment, the overflow prevention pattern may be engraved on one or more of the first electrode and the second electrode.

In an embodiment, the overflow prevention pattern may include at least one polygonal pattern.

In an embodiment, the overflow prevention pattern may include at least one of an elliptical pattern and a circular pattern.

In an embodiment, the overflow prevention pattern may include a plurality of stripe-shaped patterns formed on the first electrode and extending in a first direction. The plurality of stripe-shaped patterns may be repeatedly disposed in a second direction perpendicular to the first direction.

In an embodiment, each of the plurality of stripe-shaped patterns may have a predetermined depth.

In an embodiment, the overflow prevention pattern may include a plurality of stripe-shaped patterns repeatedly disposed on the first electrode, in a first direction, and the plurality of stripe-shaped patterns may extend in a second direction perpendicular to the first direction.

In an embodiment, each of the plurality of stripe-shaped patterns may include a stepped portion including a plurality of bottom surfaces, and the plurality of bottom surfaces may be disposed in the second direction and have different respective depths.

In an embodiment, for each of the plurality of stripe-shaped patterns, the respective depths of the plurality of bottom surfaces may increase in a direction from the second electrode.

In an embodiment, the overflow prevention pattern may include a plurality of trapezoidal patterns repeatedly disposed on the first electrode in a first direction. The plurality of trapezoidal patterns may extend in a second direction perpendicular to the first direction.

In an embodiment, widths of the plurality of trapezoidal patterns may increase in a direction away from the second electrode.

In an embodiment, the overflow prevention pattern may include a plurality of wave-shaped patterns formed on the first electrode and extending in a first direction. The plurality of wave-shaped patterns may be repeatedly disposed in a second direction perpendicular to the first direction.

Another embodiment provides a method of manufacturing a display device including: forming a first electrode and a second electrode on a pixel circuit layer; connecting a light emitting element to the first electrode and the second electrode; performing a test operation on the light emitting element; removing the light emitting element based on determining, at least in part from performing the test operation, a defect has occurred in the light emitting element; and forming an overflow prevention pattern on at least one of the first electrode and the second electrode, wherein the overflow prevention pattern is configured to prevent an overflow of a conductive material or control a direction of the overflow of the conductive material.

In an embodiment, the method may further include disposing the conductive material on the first electrode and the second electrode; and connecting a replacement light emitting element to the first electrode and the second electrode through the conductive material.

In an embodiment, the disposing of the conductive material on the first electrode and the second electrode may include spraying the conductive material onto the first electrode and the second electrode by using an inkjet method.

Another embodiment provides a method of manufacturing a display device including: forming, in a defective area, a first electrode and a second electrode including an overflow prevention pattern for preventing a conductive material from overflowing; connecting a light emitting element to the first electrode and the second electrode; performing a test operation on the light emitting element; and removing the light emitting element based on determining, at least in part from performing the test operation, a defect has occurred in the light emitting element.

In an embodiment, the method may further include disposing the conductive material on the first electrode and the second electrode; and connecting a replacement light emitting element to the first electrode and the second electrode through the conductive material.

In an embodiment, the disposing of the conductive material on the first electrode and the second electrode may include spraying the conductive material onto the first electrode and the second electrode by using an inkjet method.

Another embodiment provides an electronic device a processor to provide input image data, and a display device to display an image based on the input image data. The display device includes: a substrate; a pixel circuit layer disposed on the substrate; a first electrode formed on the pixel circuit layer; a second electrode formed on the pixel circuit layer and spaced apart from the first electrode; and a light emitting element connected to the first electrode and the second electrode through a conductive material. An overflow prevention pattern formed on at least one of the first electrode and the second electrode is configured to prevent an overflow of the conductive material or control a direction of the overflow of the conductive material.

In an embodiment, the overflow prevention pattern may be engraved on one or more of the first electrode and the second electrode.

According to a display device, a method of manufacturing the display device, and an electronic device including the display device of the present disclosure, a short circuit between an anode electrode and a cathode electrode of a light emitting element may be prevented.

### BRIEF DESCRIPTION OF THE DRAWINGS

FIG. 1 is a block diagram illustrating an embodiment of a display device.

FIG. 2 is a block diagram illustrating an embodiment of one of sub-pixels of FIG. 1.

FIG. 3 is a plan view illustrating an embodiment of a display panel of FIG. 1.

FIG. 4 is a cross-sectional view illustrating an embodiment of the display panel of FIG. 3.

FIG. 5 is a cross-sectional view illustrating another embodiment of the display panel of FIG. 3.

FIG. 6 is a plan view illustrating an embodiment of one of the pixels of FIG. 3.

FIG. 7 is a cross-sectional view taken along line I-I′ of FIG. 6.

FIG. 8 is a cross-sectional view taken along line II-II′ of FIG. 6.

FIG. 9A is a plan view illustrating a pixel from which one defective light emitting element is removed. FIG. 9B is a cross-sectional view taken along line I-I′ of FIG. 9A.

FIG. 10A is a plan view illustrating a process of disposing a conductive material on an anode electrode and a cathode electrode after a light emitting element is removed. FIG. 10B is a cross-sectional view taken along line I-I′ of FIG. 10A.

FIG. 11A is a plan view illustrating a process of connecting a light emitting element to an anode electrode and a cathode electrode through a conductive material. FIG. 11B is a cross-sectional view taken along line I-I′ of FIG. 11A.

FIG. 12A is a plan view illustrating a phenomenon in which an anode electrode and a cathode electrode are short-circuited due to overflow of a conductive material. FIG. 12B is a cross-sectional view taken along line I-I′ of FIG. 12A.

FIG. 13A is a plan view illustrating an embodiment of the present disclosure in which an overflow prevention pattern is formed on an anode electrode and a cathode electrode. FIG. 13B is a cross-sectional view taken along line I-I′ of FIG. 13A.

FIG. 14A is a plan view illustrating an embodiment of an overflow prevention pattern. FIG. 14B is a perspective view illustrating an embodiment of the overflow prevention pattern.

FIG. 15A is a plan view illustrating another embodiment of the overflow prevention pattern. FIG. 15B is a perspective view illustrating the embodiment of the overflow prevention pattern of FIG. 15A.

FIG. 16A is a plan view illustrating another embodiment of the overflow prevention pattern. FIG. 16B is a perspective view illustrating the embodiment of the overflow prevention pattern of FIG. 16A. FIG. 16C is a cross-sectional view taken along line III-III′ of FIG. 16B.

FIG. 17 is a plan view illustrating another embodiment of the overflow prevention pattern.

FIG. 18 is a plan view illustrating another embodiment of the overflow prevention pattern.

FIG. 19 is a flowchart illustrating a method of manufacturing a display device, according to an embodiment of the present disclosure.

FIG. 20 is a plan view illustrating a defective area of a display panel.

FIG. 21 is a flowchart illustrating a method of manufacturing a display device, according to another embodiment of the present disclosure.

FIG. 22 is a block diagram illustrating an embodiment of a display system.

FIGS. 23 to 26 are perspective views illustrating application examples of the display system of FIG. 22.

FIG. 27 is a schematic block diagram illustrating an electronic device including a display device in accordance with an embodiment.

FIG. 28 is a schematic diagram illustrating an example where the electronic device of FIG. 27 is a smartphone.

FIG. 29 is a schematic diagram illustrating an example where the electronic device of FIG. 27 is a tablet computer.

### DETAILED DESCRIPTION

Hereinafter, embodiments of the present disclosure will be described in detail with reference to the attached drawings. It should be noted that parts for understanding operations of the present disclosure will be described in the following description and the other parts will be omitted so as not to obscure the gist of the present disclosure. In some aspects, the present disclosure is not limited to the embodiments described herein and may be embodied in other forms. However, the embodiments described herein are provided in detail to enable those of ordinary skill in the technical field to which the present disclosure belongs to easily practice the technical idea of the present disclosure.

Throughout the specification, when a part is said to be “connected” to another part, this includes not only a case where the part is “directly connected” thereto but also a case where the part is “indirectly connected” thereto with another element therebetween. The terms used herein are intended to describe specific embodiments and are not intended to limit the present disclosure. Throughout the specification, when a part is said to “include” a certain component, this means that other components may be further included rather than excluded unless otherwise specifically stated. “At least one of X, Y, and Z”, and “at least one selected from a group consisting of X, Y, and Z” may be interpreted as one X, one Y, one Z, or any combination (for example, XYZ, XYY, YZ, or ZZ) of two or more of X, Y, and Z. Herein, “and/or” includes any combination of one or more of the components.

Herein, although terms, such as, for example, first and second, may be used to describe various components, such components are not limited to the terms. The terms are used to distinguish one component from another component. Therefore, a first component may refer to a second component without departing from the scope disclosed herein.

Spatially relative terms, such as, for example, “below”, “above,” and the like, may be used for descriptive purposes, thereby describing a relationship of one element or feature to another element(s) or feature(s) as illustrated in the drawings. The spatially relative terms are intended to include different directions in use, operation, and/or manufacturing, in addition to the direction illustrated in the drawings. In an example in which the device illustrated in the drawing is turned over, components described as being disposed “below” other components or features are disposed “above” the other components or features. Therefore, In an embodiment, the term “below” may include both above and below. Furthermore, the device may be oriented in another direction (for example, rotated 90 degrees or in another direction), and the spatially relative terms used herein are interpreted according thereto.

The term “substantially,” as used herein, means approximately or actually. The term “substantially equal” means approximately or actually equal. The term “substantially the same” means approximately or actually the same.

Various embodiments are described with reference to drawings illustrating example embodiments. Accordingly, it will be expected that the shapes may change depending on, for example, tolerances and/or manufacturing techniques. Therefore, the embodiments disclosed herein should not be construed as being limited to the illustrated specific shapes, but should be construed to include a change in shape which occurs, for example, as a result of manufacturing. As such, the shapes illustrated in the drawings may not illustrate the actual shapes of areas of a device, and the present embodiments are not limited thereto.

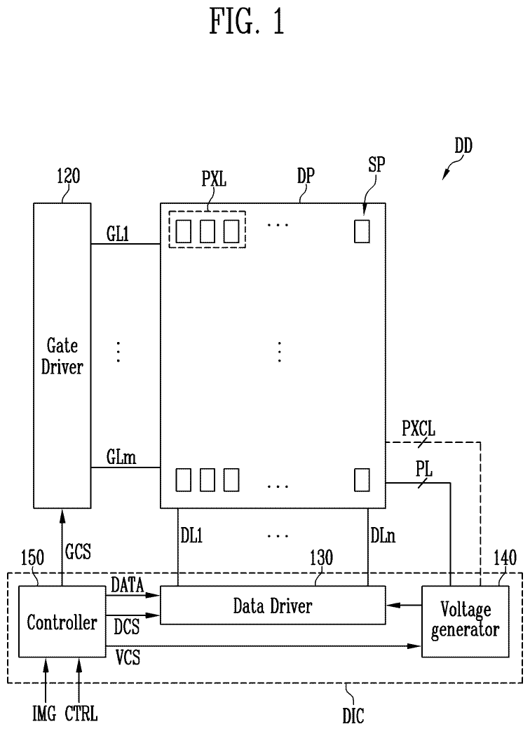

FIG. 1 is a block diagram illustrating an embodiment of a display device.

Referring to FIG. 1, a display device DD may include a display panel DP, a gate driver 120, a data driver 130, a voltage generator 140, and a controller 150.

The display panel DP includes sub-pixels SP. The sub-pixels SP may be connected to the gate driver 120 through first to m-th gate lines GL1 to GLm. The sub-pixels SP may be connected to the data driver 130 through first to n-th data lines DL1 to DLn.

The sub-pixels SP may generate light of two or more colors. For example, each of the sub-pixels SP may generate light of, for example, red, green, blue, cyan, magenta, yellow, and the like.

A pixel PXL may include two or more sub-pixels among the sub-pixels SP For example, the pixel PXL may include three sub-pixels as illustrated in FIG. 1. Accordingly, for example, the pixel PXL may emit light of various colors and various types of luminance depending on combinations of light emitted from the sub-pixels included in the pixel PXL.

The gate driver 120 is connected to the sub-pixels SP arranged in a row direction through first to m-th gate lines GL1 to GLm. The gate driver 120 may output gate signals to the first to m-th gate lines GL1 to GLm in response to a gate control signal GCS. In embodiments, the gate control signal GCS may include a start signal indicating the start of each frame, a horizontal synchronization signal, and the like.

The gate driver 120 may be disposed on one side of the display panel DP. However, embodiments of the present disclosure are not limited thereto. For example, the gate driver 120 may include two or more drivers that are physically and/or logically separated, and such drivers may be disposed on one side of the display panel DP and the other side of the display panel DP opposite to the one side. Accordingly, for example, the gate driver 120 may be disposed around the display panel DP in various forms according to the embodiments.

The data driver 130 is connected to the sub-pixels SP arranged in a column direction through first to n-th data lines DL1 to DLn. The data driver 130 receives image data DATA and a data control signal DCS from the controller 150. The data driver 130 operates in response to the data control signal DCS. In embodiments, the data control signal DCS may include a source start signal, a source shift clock signal, a source output enable signal, and the like.

The data driver 130 may receive a voltage from a voltage generator 140. The data driver 130 may apply data signals having grayscale voltages corresponding to the image data DATA to the first to n-th data lines DL1 to DLn by using the received voltages. In an example in which a gate signal is applied to each of the first to m-th gate lines GL1 to GLm, data signals corresponding to the image data DATA may be applied to the first to n-th data lines DL1 to DLm. Accordingly, the sub-pixels SP may generate light corresponding to the data signals, and the display panel DP may display an image.

In embodiments, the gate driver 120 and the data driver 130 may each include complementary metal-oxide semiconductor (CMOS) circuit elements.

The voltage generator 140 may operate in response to a voltage control signal VCS output from the controller 150. The voltage generator 140 is configured to generate a plurality of voltages and provide the generated voltages to components of the display device DD, such as, for example, the gate driver 120, the data driver 130, and the controller 150. The voltage generator 140 may generate a plurality of voltages by receiving an input voltage from the outside of the display device 100 and regulating the received voltage.

The voltage generator 140 may generate a first power voltage and a second power voltage. The generated first and second power voltages may be provided to the sub-pixels SP through power lines PL. In another embodiments, at least one of the first power voltage and the second power voltage may be provided from the outside of the display device 100.

In some aspects, the voltage generator 140 may provide various voltages and/or signals. For example, the voltage generator 140 may generate one or more initialization voltages applied to the sub-pixels SP. For example, during a sensing operation of sensing electrical characteristics of transistors and/or light emitting elements of the sub-pixels SP, a predetermined reference voltage may be applied to the first to n-th data lines DL1 to DLn, and the voltage generator 140 may generate a reference voltage and transmit the reference voltage to the data driver 130. For example, during a display operation of displaying an image on the display panel DP, common pixel control signals may be applied to sub-pixels SP, and the voltage generator 140 may generate the pixel control signals. In embodiments, the voltage generator 140 may provide the pixel control signals to the sub-pixels SP through pixel control lines PXCL. Although FIG. 1 illustrate that the pixel control lines PXCL are connected between the voltage generator 140 and the display panel DP, embodiments of the present disclosure are not limited thereto. For example, the pixel control lines PXCL may be connected between the gate driver 120 and the display panel DP. In this case, pixel control signals may be transmitted from the gate driver 120 to the sub-pixels SP through the pixel control lines PXCL.

The controller 150 controls all operations of the display device 100. The controller 150 receives input image data IMG and a control signal CTRL corresponding to the input image data IMG from the outside. In response to the control signal CTRL, the controller 150 may provide the gate control signal GCS, the data control signal DCS, and a voltage control signal VCS.

The controller 150 may convert the input image data IMG to be suitable for the display device 100 or the display panel DP and output the image data DATA. In embodiments, the controller 150 may align the input image data IMG to be suitable for the sub-pixels SP of a row unit and output the image data DATA.

Two or more of the data driver 130, the voltage generator 140, and the controller 150 may be mounted on a single integrated circuit. As illustrated in FIG. 1, the data driver 130, the voltage generator 140, and the controller 150 may be included in a driver integrated circuit DIC. In this case, the data driver 130, the voltage generator 140, and the controller 150 may be functionally separate components in a single driver integrated circuit DIC. In other embodiments, at least one of the data driver 130, the voltage generator 140, and the controller 150 may be provided as a separate component from the driver integrated circuit DIC.

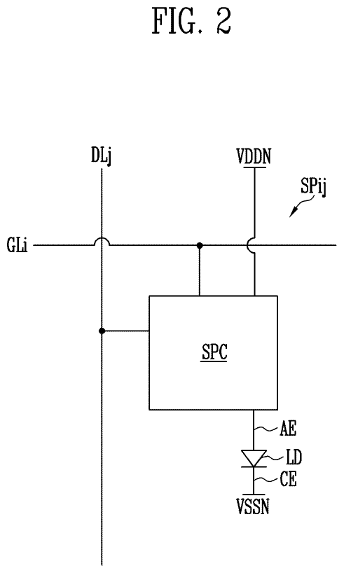

FIG. 2 is a block diagram illustrating an embodiment of one of the sub-pixels SP of FIG. 1. FIG. 2 illustrates an example of a sub-pixel SPij arranged in the i-th row (i is an integer greater than or equal to 1 and less than or equal to m) and the j-th column (j is an integer greater than or equal to 1 and less than or equal to n) among the sub-pixels SP of FIG. 1.

Referring to FIG. 2, the sub-pixel SPij may include a sub-pixel circuit SPC and a light emitting element LD.

The light emitting element LD may be connected between a first power supply voltage node VDDN and a second power supply voltage node VSSN. The first power voltage node VDDN is connected to one of the power lines PL of FIG. 1 and receives a first power voltage. The second power voltage node VSSN is connected to another of the power lines PL of FIG. 1 and receives a second power voltage. The first power voltage may have a higher voltage level than the second power voltage.

The light emitting element LD is connected between an anode electrode AE and a cathode electrode CE. The anode electrode AE may be connected to the first power voltage node VDDN through the sub-pixel circuit SPC. For example, the anode electrode AE may be connected to the first power voltage node VDDN through one or more transistors included in the sub-pixel circuit SPC. The cathode electrode CE may be connected to the second power voltage node VSSN. The light emitting element LD is configured to emit light according to a current flowing from the anode electrode AE to the cathode electrode CE.

The sub-pixel circuit SPC may be connected to the i-th gate line GLi among the first to m-th gate lines GL1 to GLm of FIG. 1 and the j-th data line DLj among the first to n-th data lines DL1 to DLn of FIG. 1. In response to a gate signal received through the i-th gate line GLi, the sub-pixel circuit SPC controls the light emitting element LD to emit light according to a data signal received through the j-th data line DLj. In embodiments, the sub-pixel circuit SPC may be further connected to the pixel control lines PXCL of FIG. 1. In this case, the sub-pixel circuit SPC may further control the light emitting element LD in response to pixel control signals received through the pixel control lines PXCL.

For the operations, the sub-pixel circuit SPC may include circuit elements, for example, transistors and one or more capacitors.

The transistors of the sub-pixel circuit SPC may include P-type transistors and/or N-type transistors. In embodiments, the transistors of the sub-pixel circuit SPC may each include a metal oxide silicon field effect transistor (MOSFET). In embodiments, the transistors of the sub-pixel circuit SPC may each include an amorphous silicon semiconductor, a monocrystalline silicon semiconductor, a polycrystalline silicon semiconductor, an oxide semiconductor, or so on.

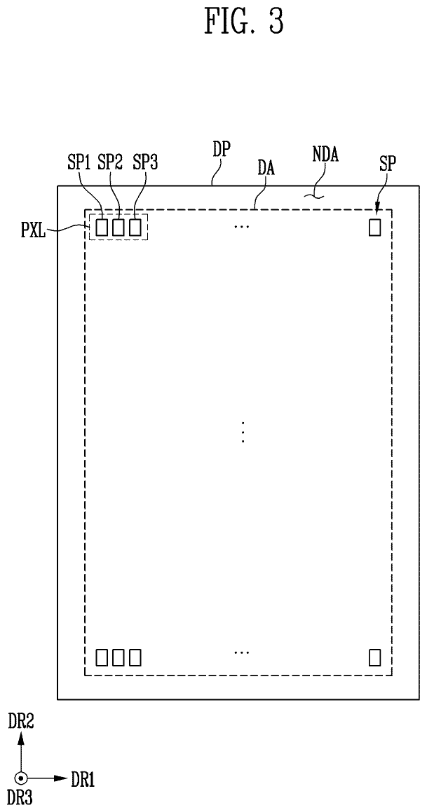

FIG. 3 is a plan view illustrating an embodiment of the display panel DP of FIG. 1.

Referring to FIG. 3, the display panel DP may include a display area DA and a non-display area NDA. The display panel DP displays an image through the display area DA. The non-display area NDA is disposed around the display area DA.

The display panel DP includes the sub-pixels SP in the display area DA. The sub-pixels SP may be arranged in a first direction DR1 and a second direction DR2 intersecting the first direction DR1. For example, the sub-pixels SP may be arranged in a matrix form along the first direction DR1 and the second direction DR2. In another example, the sub-pixels SP may be arranged in a zigzag form in the first direction DR1 and the second direction DR2. The arrangement of the sub-pixels SP may change based on embodiments. The first direction DR1 may be a row direction, and the second direction DR2 may be a column direction.

Two or more sub-pixels among the plurality of sub-pixels SP may constitute one pixel PXL. Although FIG. 3 illustrates that the pixel PXL include three sub-pixels SP1 to SP3, the embodiments are not limited thereto. For example, the pixel PXL may include two sub-pixels. Hereinafter, for the sake of convenience of description, in some examples, it is assumed that the pixel PXL includes a first, second, and third sub-pixels SP1 to SP3.

The first to third sub-pixels SP1 to SP3 may each generate light of one of various colors, such as, for example, red, green, blue, cyan, magenta, and yellow. Hereinafter, for the sake of clear and concise description, in an example, it is assumed that the first sub-pixel SP1 is configured to generate red light, the second sub-pixel SP2 is configured to generate green light, and the third sub-pixel SP3 is configured to generates blue light.

The first to third sub-pixels SP1 to SP3 may each include at least one light emitting element configured to generate light. In embodiments, the light emitting elements of the first to third sub-pixels SP1 to SP3 may generate light of the same color. For example, the light emitting elements of the first to third sub-pixels SP1 to SP3 may generate blue light. In other embodiments, the light emitting elements of the first to third sub-pixels SP1 to SP3 may generate light of different colors. For example, the light emitting elements of the first to third sub-pixels SP1 to SP3 may respectively generate red light, green light, and blue light.

A self-luminous display panel, such as, for example, a light emitting diode (LED) display panel that uses micro-scale or nano-scale light emitting diodes as light emitting elements, or an organic light emitting display (OLED) panel that uses organic light emitting diodes as light emitting elements, may be used as the display panel DP.

Components for controlling the sub-pixels SP may be disposed in the non-display area NDA. Wires connected to the sub-pixels SP, for example, the first to m-th gate lines GL1 to GLm, the first to n-th data lines DL1 to DLn, the power lines PL, and the pixel control lines PXCL of FIG. 1, may be disposed in the non-display area NDA.

At least one of the gate driver 120, the data driver 130, the voltage generator 140, and the controller 150 of FIG. 1 may be disposed in the non-display area NDA of the display panel DP. In embodiments, the gate driver 120 may be disposed in the non-display area NDA. In this case, the data driver 130, the voltage generator 140, and the controller 150 may be implemented as the driver integrated circuit DIC of FIG. 1 separate from the display panel DP, and the driver integrated circuit DIC may be connected to the wires disposed in the non-display area NDA. In other embodiments, the gate driver 120 may be implemented as a single integrated circuit, which is separate from the display panel DP, together with the data driver 130, the voltage generator 140, and the controller 150.

In embodiments, the display area DA may have various shapes. The display area DA may have a shape of a closed loop including straight and/or curved sides. For example, the display area DA may have a shape, such as, for example, a polygon, a circle, a semicircle, or an ellipse.

In embodiments, the display panel DP may have a flat display surface. In other embodiments, the display panel DP may have an at least partially rounded display surface. In embodiments, the display panel DP may be bendable, foldable, or rollable. In this case, at least one of the display panel DP and a substrate of the display panel DP may include a material with flexibility.

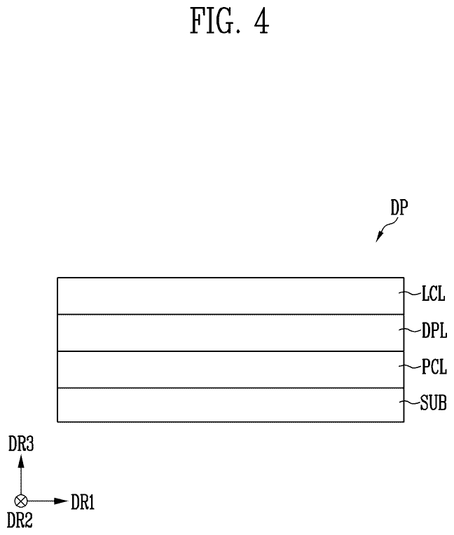

FIG. 4 is a cross-sectional view illustrating an embodiment of the display panel DP of FIG. 3.

Referring to FIG. 4, the display panel DP may include a substrate SUB, and a pixel circuit layer PCL, a display panel layer DPL, and a light conversion layer LCL which are sequentially stacked on the substrate SUB in a third direction DR3 intersecting the first and second directions DR1 and DR2.

The substrate SUB may be formed of an insulating material, such as, for example, glass or resin. For example, the substrate SUB may include a glass substrate. In another example, the substrate SUB may include a polyimide (PI) substrate. In another example, the substrate SUB may include a silicon wafer substrate formed through a semiconductor process.

In embodiments, the substrate SUB may be formed of a flexible material that is bendable or foldable and may have a single-layer structure or a multilayer structure. For example, the flexible material may include at least one of polystyrene, polyvinyl alcohol, polymethyl methacrylate, polyethersulfone, polyacrylate, polyetherimide, polyethylene naphthalate, polyethylene terephthalate, polyphenylene sulfide, polyarylate, polyimide, polycarbonate, triacetate cellulose, and cellulose acetate propionate. However, the embodiments are not limited thereto.

The pixel circuit layer PCL is disposed on the substrate SUB. The pixel circuit layer PCL may include insulating layers and semiconductor patterns and conductive patterns disposed between the insulating layers. The conductive patterns of the pixel circuit layer PCL may function as circuit elements, wires, and the like.

The circuit elements of the pixel circuit layer PCL may include the sub-pixel circuits SPC (see FIG. 2) of each of the sub-pixels SP of FIG. 3. In other words, the circuit elements of the pixel circuit layer PCL may be provided as transistors and one or more capacitors of the sub-pixel circuit SPC.

The wires of the pixel circuit layer PCL may include wires connected to the sub-pixels SP. The wires of the pixel circuit layer PCL may include various signal lines and/or voltage lines supportive of driving the display panel layer DPL.

The display panel layer DPL is disposed on the pixel circuit layer PCL. The display panel layer DPL may include light emitting elements of the sub-pixels SP.

The light conversion layer LCL may be disposed on the display panel layer DPL. The light conversion layer LCL may include light conversion patterns including color conversion particles and/or scattering particles. For example, the color conversion particles may include quantum dots. The quantum dots may change wavelengths (or color) of the light emitted from the display panel layer DPL. In embodiments, the light conversion patterns may be omitted.

The light conversion layer LCL may further include a color filter layer including color filters. The color filter may selectively transmit light of a specific wavelength (or, a specific color) therethrough. In embodiments, the color filter layer may be omitted.

A window may be provided on the light conversion layer LCL to protect an exposed surface (or an upper surface) of the display panel DP. The window may protect the display panel DP from external impact. The window may be bonded to the light conversion layer LCL through an optically transparent adhesive (or bonding) member. The window may have a multilayer structure selected from a glass substrate, a plastic film, and a plastic substrate. The multilayer structure may be formed through a continuous process or an adhesive process using an adhesive layer. The entirety or a part of the window may have flexibility.

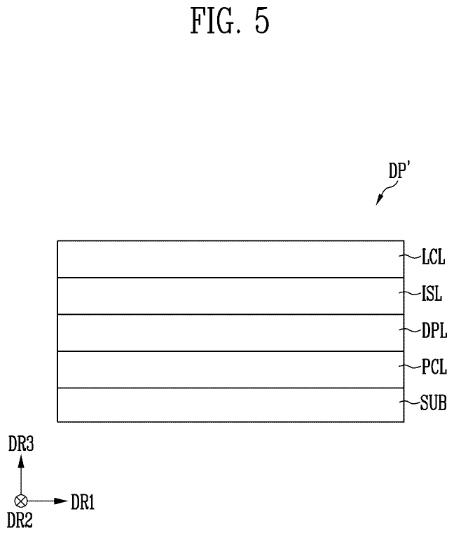

FIG. 5 is a cross-sectional view illustrating another embodiment of the display panel of FIG. 3.

Referring to FIG. 5, a display panel DP′ may include a substrate SUB, a pixel circuit layer PCL, a display panel layer DPL, an input sensing layer ISL, and a light conversion layer LCL. The substrate SUB, the pixel circuit layer PCL, the display panel layer DPL, and the light conversion layer LCL are respectively configured similarly to the substrate SUB, the pixel circuit layer PCL, the display panel layer DPL, and the light conversion layer LCL described with reference to FIG. 4. Hereinafter, repeated descriptions of like elements are omitted for brevity.

The input sensing layer ISL may sense a user input on an upper surface (or a display surface) of the display panel DP′. The input sensing layer ISL may include a configuration that is suitable for sensing an external object, such as, for example, a user's hand or a pen. For example, the input sensing layer ISL may include touch electrodes.

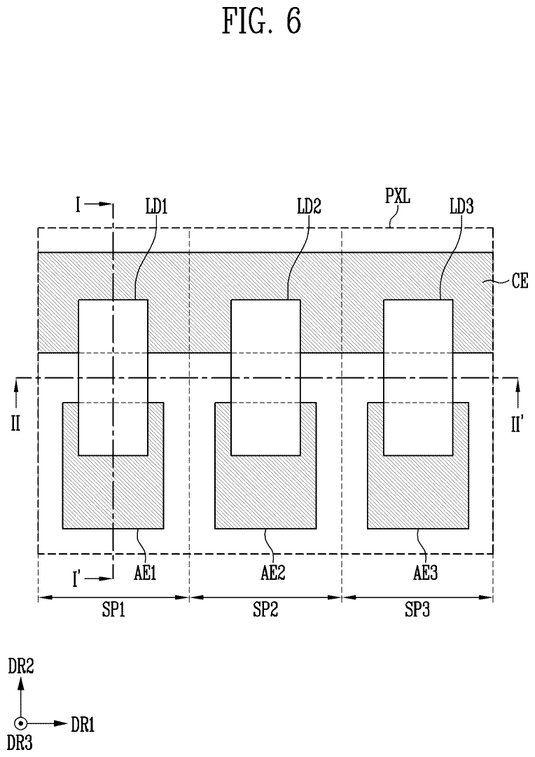

FIG. 6 is a plan view illustrating an embodiment of one of the pixels PXL of FIG. 3.

Referring to FIG. 6, the pixel PXL may include first to third sub-pixels SP1 to SP3. The first to third sub-pixels SP1 to SP3 may be arranged in a first direction DR1. However, an arrangement of the first to third sub-pixels SP1 to SP3 is not limited thereto and may change based on embodiments. For example, the first to third sub-pixels SP1 to SP3 may be arranged in a zigzag form.

The first to third sub-pixels SP1 to SP3 may be respectively arranged in first anode electrode AE1 to third anode electrode AE3. The first anode electrode AE1 may be provided as the anode electrode AE (see FIG. 2) connected to the sub-pixel circuit SPC (see FIG. 2) of the first sub-pixel SP1. The second anode electrode AE2 may be provided as the anode electrode AE connected to the sub-pixel circuit SPC of the second sub-pixel SP2. The third anode electrode AE3 may be provided as the anode electrode AE connected to the sub-pixel circuit SPC of the third sub-pixel SP3.

The cathode electrode CE may be spaced apart from the first to third anode electrodes AE1 to AE3. The cathode electrode CE may be disposed at the same height as the first to third anode electrodes AE1 to AE3. The cathode electrode CE may be spaced apart from the first to third anode electrodes AE1 to AE3 in a second direction DR2. In embodiments, the cathode electrode CE may be extended in the first direction DR1 and used as a common electrode for the pixel PXL and other pixels adjacent to the pixel PXL. Although not illustrated in FIG. 6, the cathode electrode CE may be extended in the second direction DR2 as well as the first direction DR1 and used as a common electrode for all of the sub-pixels SP of FIG. 3. Accordingly, for example, the cathode electrode CE may have various shapes.

First, second, and third light emitting elements LD1, LD2, and LD3 may be respectively disposed on the first to third anode electrodes AE1 to AE3 and the cathode electrode CE. The first light emitting element LD1 may be electrically connected to the first anode electrode AE1 and the cathode electrode CE. The first light emitting element LD1 may be provided as the light emitting element LD (see FIG. 2) connected to the sub-pixel circuit SPC of the first sub-pixel SP1. The second light emitting element LD2 may be electrically connected to the second anode electrode AE2 and the cathode electrode CE. The second light emitting element LD2 may be provided as the light emitting element LD connected to the sub-pixel circuit SPC of the second sub-pixel SP2. The third light emitting element LD3 may be electrically connected to the third anode electrode AE3 and the cathode electrode CE. The third light emitting element LD3 may be provided as the light emitting element LD connected to the sub-pixel circuit SPC of the third sub-pixel SP3.

The first light emitting element LD1, the second light emitting element LD2, and the third light emitting element LD3 may be inorganic light emitting diodes each including an inorganic light emitting material. However, the embodiments are not limited thereto, and for example, organic light emitting diodes may be used for the first to third light emitting elements LD1 to LD3.

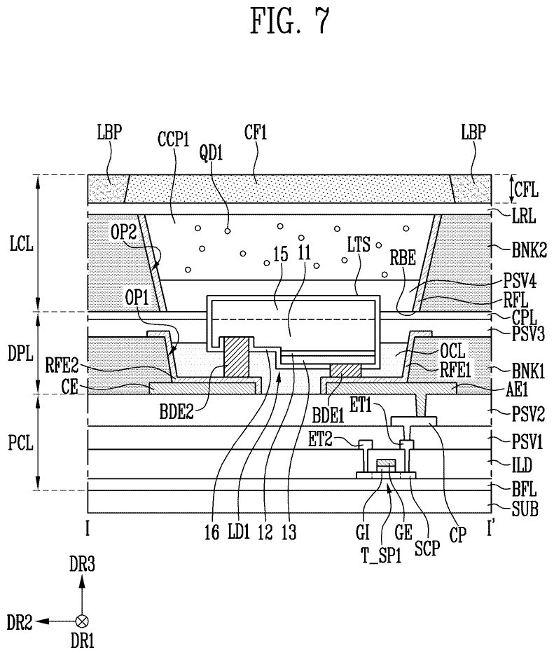

FIG. 7 is a cross-sectional view taken along line I-I′ of FIG. 6.

Referring to FIGS. 6 and 7, the pixel circuit layer PCL, the display panel layer DPL, and the light conversion layer LCL may be sequentially arranged on the substrate SUB.

The pixel circuit layer PCL may include insulating layers, semiconductor patterns, and conductive patterns stacked on the substrate SUB. The insulating layers may include a buffer layer BFL, one or more interlayer insulating layers ILD, and one or more passivation layers PSV1 and PSV2. The semiconductor patterns and conductive patterns may be disposed between the insulating layers. The conductive patterns may include at least one of copper (Cu), molybdenum (Mo), tungsten (W), aluminum neodymium (AlNd), titanium (Ti), aluminum (Al), and silver (Ag).

As described with reference to FIG. 2, the sub-pixel circuit SPC (see FIG. 2) of each of the first to third sub-pixels SP1 to SP3 may include transistors and one or more capacitors. The semiconductor patterns and conductive patterns of the pixel circuit layer PCL may function as the transistors and capacitors of the sub-pixel circuit SPC. In some aspects, the conductive patterns of the pixel circuit layer PCL may further function as wires, for example, the first to m-th gate lines GL1 to GLm, the first to n-th data lines DL1 to DLn, the power lines PL, and the pixel control lines PXCL illustrated in FIG. 1.

The buffer layer BFL may be disposed on one surface of the substrate SUB. The buffer layer BFL may prevent impurities from diffusing into circuit elements and wires included in the pixel circuit layer PCL. The buffer layer BFL may include an inorganic insulating layer including an inorganic material. In embodiments, the buffer layer BFL may include at least one of metal oxides, such as, for example, silicon nitride (SiNₓ), silicon oxide (SiOₓ), silicon oxynitride (SiOₓN_{y}), and aluminum oxide (AlOₓ). The buffer layer BFL may be provided as a single layer or multiple layers. In an example in which the buffer layer BFL includes multiple layers, the multiple layers may be formed of the same material or may be formed of different materials.

In embodiments, one or more barrier layers may be disposed between the substrate SUB and the buffer layer BFL. The one or more barrier layers may each include polyimide.

A transistor T_SP1 may be disposed on the buffer layer BFL. The transistor T_SP1 may be any one of transistors of the sub-pixel circuit SPC included in the first sub-pixel SP1. For example, the transistor T_SP1 may be understood as a transistor connected to the first anode electrode AE1 among the transistors of the sub-pixel circuit SPC.

The transistor T_SP1 may include a semiconductor pattern SCP, a gate electrode GE, a first terminal ET1, and a second terminal ET2. The first terminal ET1 may be any one of a source electrode and a drain electrode, and the second terminal ET2 may be the other one of the source electrode and the drain electrode. For example, the first terminal ET1 may be the source electrode, and the second terminal ET2 may be the drain electrode.

The semiconductor pattern SCP may be disposed on a buffer layer BFL. The semiconductor pattern SCP may include a first contact area in contact with the first terminal ET1 and a second contact area in contact with the second terminal ET2. An area between the first contact area and the second contact area may be a channel area. The channel area may overlap the gate electrode GE of the transistor T_SP1. The channel area may be a semiconductor pattern that is not doped with an impurity and may be an intrinsic semiconductor. The first contact area and the second contact area may be semiconductor patterns doped with impurities. For example, a p-type impurity may be used as the impurity, but the embodiments are not limited thereto.

The semiconductor pattern SCP may include any one of various types of semiconductors, for example, an amorphous silicon semiconductor, a monocrystalline silicon semiconductor, a polycrystalline silicon semiconductor, a polysilicon semiconductor, a low temperature polysilicon semiconductor, and an oxide semiconductor.

The Interlayer insulating layers ILD may be sequentially stacked on the semiconductor pattern SCP. The interlayer insulating layers ILD may each be an inorganic insulating layer including an inorganic material. For example, the interlayer insulating layers ILD may each include at least one of metal oxides, such as, for example, silicon nitride (SiNₓ), silicon oxide (SiOₓ), silicon oxynitride (SiOₓN_{y}), and aluminum oxide (AlOₓ). However, the interlayer insulating layers ILD are not limited thereto. For example, the interlayer insulating layers ILD may each include an organic insulating layer including an organic material.

The interlayer insulating layers ILD may electrically isolate conductive patterns and/or semiconductor patterns disposed between the interlayer insulating layers ILD. For example, the interlayer insulating layers ILD may include a gate insulating layer GI disposed on a semiconductor pattern SCP. The gate insulating layer GI may be disposed between the semiconductor pattern SCP and the gate electrode GE such that the gate electrode GE is spaced apart from the semiconductor pattern SCP. In embodiments, the gate insulating layer GI may be entirely provided on a surface of the semiconductor pattern SCP and over the buffer layer BFL, and the gate insulating layer GI may cover the semiconductor pattern SCP and the buffer layer BFL. As the number of layers associated with implementing the conductive patterns and/or semiconductor patterns increases, the number of interlayer insulating layers ILD may increase.

The gate electrode GE is disposed on the gate insulating layer GI. The gate electrode GE may overlap a channel area of the semiconductor pattern SCP. In embodiments, the gate electrode GE may be provided as a single layer including at least one of copper (Cu), molybdenum (Mo), tungsten (W), aluminum neodymium (AlNd), titanium (Ti), aluminum (Al), and silver (Ag). In embodiments, the gate electrode GE may be provided as a multilayer including at least one of low-resistance materials, such as, for example, molybdenum (Mo), titanium (Ti), copper (Cu), aluminum (Al), and silver (Ag).

The first termina ET1 and the second terminal ET2 are disposed on the interlayer insulating layers ILD. The first and second terminals ET1 and ET2 may be in contact with the semiconductor pattern SCP through contact holes penetrating the interlayer insulating layers ILD. The first and second terminals ET1 and ET2 may be respectively in contact with first and second contact areas of the semiconductor pattern SCP. The first and second terminals ET1 and ET2 may each include at least one material selected from a group including copper (Cu), molybdenum (Mo), tungsten (W), aluminum neodymium (AlNd), titanium (Ti), copper (Cu), aluminum (Al), and silver (Ag).

Although FIG. 7 illustrates that the first and second terminals ET1 and ET2 are separate electrodes electrically connected to the semiconductor pattern SCP, the embodiments are not limited thereto. In the embodiments, the first terminal ET1 may be a first contact area adjacent to one side of the channel area of the semiconductor pattern SCP, and the second terminal ET2 may be a second contact area adjacent to the other side of the channel area. In this case, the first terminal ET1 may be electrically connected to the light emitting element LD through a connection member, such as, for example, a bridge electrode, disposed on at least one of the interlayer insulating layers ILD.

In embodiments, the transistor T_SP1 may be configured as a low-temperature poly-silicon transistor. However, the embodiments are not limited thereto. For example, the transistor T_SP1 may also be configured as an oxide semiconductor transistor. In embodiments, a sub-pixel circuit of the first sub-pixel SP1 may include transistors of different types. For example, the transistor T_SP1 may be configured as a low-temperature poly-silicon transistor, and another transistor of the first sub-pixel SP1 may be configured as an oxide semiconductor transistor. In this case, an oxide semiconductor of the oxide semiconductor transistor may be disposed on one or more of the interlayer insulating layers ILD other than the insulating layer on which the semiconductor pattern SCP of the transistor T_SP1 is disposed.

Although the embodiments describes that the transistor T_SP1 is an example of a transistor having a top gate structure, the embodiments are not limited thereto. For example, the transistor T_SP1 may be a transistor having a bottom gate structure. In some aspects, the structure of the transistor T_SP1 may be variously changed.

At least some of various wires of the display panel DP and/or the display device DD may be further disposed on the interlayer insulating layers ILD.

A first passivation layer PSV1 may be disposed on the first transistor T_SP1 to a third transistor T_SP3. The first passivation layer PSV1 may be referred to as a protective layer or a via layer. The first passivation layer PSV1 may protect components disposed thereunder and may provide a flat upper surface.

A connection pattern CP may be disposed on the first passivation layer PSV1. The connection pattern CP may pass through the first passivation layer PSV1 and be connected to the first terminal ET1 of the transistor T_SP1. The connection pattern CP may include at least one of copper (Cu), molybdenum (Mo), tungsten (W), aluminum neodymium (AlNd), titanium (Ti), copper (Cu), aluminum (Al), and silver (Ag).

At least some of various wires of the display panel DP and/or the display device DD may be further disposed on the first passivation layer PSV1.

A second passivation layer PSV2 is disposed on the connection pattern CP and the first passivation layer PSV1. The second passivation layer PSV2 may protect components disposed thereunder and provide a flat upper surface.

The first and second passivation layers PSV1 and PSV2 may each include an inorganic insulating layer including an inorganic material and/or an organic insulating layer including an organic material. The inorganic insulating layer may include at least one of metal oxides, such as, for example, silicon oxide (SiOₓ), silicon nitride (SiNₓ), silicon oxynitride (SiOₓN_{y}), and aluminum oxide (AlOₓ). The organic insulating layer may include at least one of, for example, an acrylic resin, an epoxy resin, a phenolic resin, a polyamide resin, a polyimide rein, an unsaturated polyester resin, a poly-phenylene ether resin, a poly-phenylene sulfide resin, and a benzocyclobutene resin.

The first and second passivation layers PSV1 and PSV2 may include the same material as any one of the interlayer insulating layers ILD, but the embodiments are not limited thereto. The first and second passivation layers PSV1 and PSV2 may each be provided as a single layer, but may also be provided as a multilayer.

The display panel layer DPL may be disposed on the second passivation layer PSV2. The display panel layer DPL may include the first anode electrode AE1, the cathode electrode CE, a first bank BNK1, a first reflective electrode RFE1, a second reflective electrode RFE2, a first light emitting element LD1, an overcoat layer OCL, a third passivation layer PSV3, and a capping layer CPL.

The first anode electrode AE1 and the cathode electrode CE are disposed on the pixel circuit layer PCL.

The first anode electrode AE1 may be electrically connected to the connection electrode CP through a contact hole penetrating the second passivation layer PSV2. Accordingly, for example, the first anode electrode AE1 may be electrically connected to the first transistor T_SP1.

The cathode electrode CE may be spaced apart from the first anode electrode AE1 in a first direction DR1. The cathode electrode CE may be electrically connected to the second power supply voltage node VSSN of FIG. 2. Accordingly, a second power voltage applied to the second power voltage node VSSN may be transmitted to the cathode electrode CE.

The first bank BNK1 may be disposed on the first anode electrode AE1 and the cathode electrode CE. The first bank BNK1 may have a first opening OP1 exposing parts of the first anode electrode AE1 and the cathode electrode CE. The first light emitting element LD1 may be disposed in the first opening OP1 of the first bank BNK1. Accordingly, for example, the first bank BNK1 may be provided as a pixel definition layer that defines an area where the first light emitting element LD1 is disposed.

The first bank BNK1 may include a light-blocking material, thereby preventing light mixing between adjacent sub-pixels. In embodiments, the first bank BNK1 may include an organic material. For example, the first bank BNK1 may include an organic insulating material, such as, for example, an acrylic resin, an epoxy resin, a phenolic resin, a polyamide resin, or a polyimide resin.

The first reflective electrode RFE1 may be disposed on an exposed portion of the first anode electrode AE1 and on a side surface of the first bank BNK1 adjacent to the first anode electrode AE1. The second reflective electrode RFE2 may be disposed on an exposed portion of the cathode electrode CE and on a side surface of the first bank BNK1 adjacent to the cathode electrode CE. The first and second reflective electrodes RFE1 and RFE2 may each include a conductive material that is suitable for reflecting light. Accordingly, the light emission efficiency of the first light emitting element LD1 may be increased. In embodiments, the first and second reflective electrodes RFE1 and RFE2 may each include at least one of aluminum (Al), silver (Ag), magnesium (Mg), platinum (Pt), palladium (Pd), gold (Au), nickel (Ni), neodymium (Nd), iridium (Ire), chromium (Cr), titanium (Ti), and an alloy of two or more materials selected therefrom. However, the embodiments are not limited thereto.

The first light emitting element LD1 is electrically connected to the first anode electrode AE1 through the first reflective electrode RFE1. The first light emitting element LD1 is electrically connected to the cathode electrode CE through the second reflective electrode RFE2. The first light emitting element LD1 may be bonded and coupled to the first and second reflective electrodes RFE1 and RFE2.

The first light emitting element LD1 may include a first semiconductor layer 11, an active layer 12, a second semiconductor layer 13, and an auxiliary layer 15. The first light emitting element LD1 includes a light emitting laminate in which an auxiliary layer 15, a first semiconductor layer 11, an active layer 12, and a second semiconductor layer 13 are sequentially laminated.

The first light emitting element LD1 includes a first bonding electrode BDE1 and a second bonding electrode BDE2 facing in the same direction (for example, in a direction opposite to the third direction DR3). The first bonding electrode BDE1 may be connected to the second semiconductor layer 13. The second bonding electrode BDE2 may be connected to the first semiconductor layer 11 exposed by etching the second semiconductor layer 13 and the active layer 12. The first light emitting element LD1 may be a flip chip type light emitting element.

The first semiconductor layer 11 provides electrons to the active layer 12. The first semiconductor layer 11 may include, for example, at least one n-type semiconductor layer. For example, the first semiconductor layer 11 may include any one of semiconductor materials, such as, for example, gallium nitride (Gan), aluminum gallium nitride (AlGaN), indium gallium nitride (Ingang), aluminum nitride (AlN), and indium nitride (In), and may be an n-type semiconductor layer doped with a first conductive dopant (or an n-type dopant), such as, for example, silicon (Si), germanium (Ge), or tin (Sn). However, the material forming the first semiconductor layer 11 is not limited thereto, and various other materials may also form the first semiconductor layer 11. In an embodiment of the present disclosure, the first semiconductor layer 11 may include a gallium nitride (Gan) semiconductor material doped with a first conductive dopant (or an n-type dopant). According to an embodiment, the first semiconductor layer 11 may constitute an n-type semiconductor layer together with the auxiliary layer 15.

The active layer 12 is disposed on the first semiconductor layer 11 and may be an area where electrons recombine with holes. As electrons recombine with holes in the active layer 12, the electrons and holes are shifted to a lower energy level, and thereby, light having a wavelength corresponding thereto may be generated. The active layer 12 may be formed to have a single or multiple quantum well structure. In an example in which the active layer 12 is formed to have the multiple quantum well structure, units including a barrier layer, a strain reinforcing layer, and a well layer may be repeatedly stacked to form the active layer 12. However, embodiments of the active layer 12 are not limited thereto.

The second semiconductor layer 13 is disposed on the active layer 12 and provides holes to the active layer 12. The second semiconductor layer 13 may include a semiconductor layer of a different type from the first semiconductor layer 11. For example, the second semiconductor layer 13 may include at least one p-type semiconductor layer. For example, the second semiconductor layer 13 may include at least one of gallium nitride (Gan), aluminum gallium nitride (AlGaN), indium gallium nitride (Ingang), aluminum nitride (AlN), and indium nitride (In), and may be a p-type semiconductor layer doped with a second conductive dopant (or a p-type dopant), such as, for example, magnesium (Mg), zinc (Zn), calcium (Ca), strontium (Sr), or barium (Ba). However, the material forming the second semiconductor layer 13 is not limited thereto, and various other materials may form the second semiconductor layer 13. In an embodiment of the present disclosure, the second semiconductor layer 13 may include a gallium nitride (GaN) semiconductor material doped with a second conductive dopant (or a p-type dopant).

The auxiliary layer 15 may include a gallium nitride (GaN) semiconductor material that is not doped with an impurity and may constitute an n-type semiconductor layer together with the first semiconductor layer 11.

The first bonding electrode BDE1 may be electrically connected to the second semiconductor layer 13. The second bonding electrode BDE2 may be electrically connected to the first semiconductor layer 11. The first and second bonding electrodes BDE1 and BDE2 may each include a eutectic metal.

The first light emitting element LD1 may further include an insulating layer 16 that covers an outer surface of a light emitting stack member. The insulating layer 16 may prevent an electrical short circuit that may occur when the active layer 12 comes into contact with a conductive material other than the first and second semiconductor layers 11 and 13. The insulating layer 16 may include a transparent insulating material. The insulating layer 16 is configured to expose lower surfaces of the first and second bonding electrodes BDE1 and BDE2.

The lower surface of the first bonding electrode BDE1 is in contact with the first reflective electrode RFE1. Accordingly, the first bonding electrode BDE1 is electrically connected to the first anode electrode AE1 through the first reflective electrode RFE1. The lower surface of the second bonding electrode BDE2 is in contact with the second reflective electrode RFE2. Accordingly, the second bonding electrode BDE2 is electrically connected to the cathode electrode CE through the second reflective electrode RFE2.

The overcoat layer OCL may be disposed within the first opening OP1 in which the first and second reflective electrodes RFE1 and RFE2 and the first light emitting element LD1 are disposed. The overcoat layer (OCL may fix the first light emitting element LD1 bonded to the first and second reflective electrodes RFE1 and RFE2 so as not to move. In some aspects, the overcoat layer OCL may protect the components disposed thereunder from foreign materials, such as, for example, dust, moisture, and the like. For example, the overcoat layer OCL may include at least one of an inorganic insulating layer and an organic insulating layer. For example, the overcoat layer OCL may include epoxy, but the embodiments are not limited thereto.

The third passivation layer PSV3 is disposed on the first bank BNK1 and the overcoat layer OCL. The third passivation layer PSV3 may protect the components disposed thereunder and provide a flat upper surface. The third passivation layer PSV3 may include the same material as one of the first and second passivation layers PSV1 and PSV2, but embodiments are not limited thereto.

In embodiments, the third passivation layer PSV3 may not be disposed on an upper surface LTS of the first light emitting element LD1. The first light emitting element LD1 may protrude into the light conversion layer LCL. The first light emitting element LD1 may be at least partially disposed within the second opening OP2 of the second bank BNK2. For example, a height of the upper surface LTS of the first light emitting element LD1 from the substrate SUB may be higher than a lowermost end RBE of the reflection layer RFL. Accordingly, the light emitted from the first light emitting element LD1 may be provided to the light conversion layer LCL at a relatively high rate.

The capping layer CPL is disposed on the third passivation layer PSV3. The capping layer CPL may protect components under the capping layer CPL, such as, for example, the first light emitting element LD1, from external moisture and humidity. In embodiments, the capping layer CPL may not be disposed on an upper surface of the first light emitting element LD1. In other embodiments, the capping layer CPL may entirely cover the first light emitting element LD1 and the third passivation layer PSV3. The capping layer CPL may include at least one of metal oxides, such as, for example, silicon nitride (SiNₓ), silicon oxide (SiOₓ), silicon oxynitride (SiOₓN_{y}), and aluminum oxide (AlOₓ). However, a material of the capping layer CPL is not limited thereto.

As described herein, the pixel circuit layer PCL and the display panel layer DPL of the first sub-pixel SP1 are described. Each of the second and third sub-pixels SP2 and SP3 of FIG. 6 may also be configured in the same manner as the first sub-pixel SP1, to the extent not otherwise described herein.

The light conversion layer LCL is disposed on the capping layer CPL. The light conversion layer LCL may include the second bank BNK2, the reflective layer RFL, a fourth passivation layer PSV4, a first light conversion pattern CCP1, a low-refractive layer LRL, and a color filter layer CFL.

The second bank BNK2 is disposed on the capping layer CPL. The second bank BNK2 may overlap the first bank BNK1. The second bank BNK2 may have a second opening OP2 that overlaps the first opening OP1.

The second bank BNK2 is configured to include a light-shielding material to prevent light mixing between adjacent sub-pixels. In embodiments, the second bank BNK2 may include an organic material. For example, the second bank BNK2 may include an organic insulating material, such as, for example, an acrylic resin, an epoxy resin, a phenolic resin, a polyamide resin, or a polyimide resin.

The reflective layer RFL may be disposed on side surfaces of the second bank BNK2 adjacent to the second opening OP2. The reflective layer RFL is configured to reflect incident light, and accordingly, light emission efficiency is increased. The reflective layer RFL may include a material that is suitable for reflecting light. The reflective layer RFL may include at least one of aluminum (Al), silver (Ag), magnesium (Mg), platinum (Pt), palladium (Pd), gold (Au), nickel (Ni), neodymium (Nd), iridium (Ire), chromium (Cr), titanium (Ti), and an alloy of two or more materials selected therefrom. However, the embodiments are not limited thereto.

The fourth passivation layer PSV4 is disposed on the capping layer CPL within the second opening OP2. The fourth passivation layer PSV4 protects the components disposed thereunder and may provide a flat upper surface. The fourth passivation layer PSV4 may include the same material as any one of the first to third passivation layers PSV1 to PSV3, but the embodiments are not limited thereto.

The first light conversion pattern CCP1 may be disposed on the fourth passivation layer PSV4 within the second opening OP2.

The first light conversion pattern CCP1 may include color conversion particles and/or scattering particles. The color conversion particles may change a wavelength of incident light to convert the incident light into light of a different color. In some aspects, the color conversion particles may scatter the incident light. In embodiments, the color conversion particles may be quantum dots. The scattering particles may scatter the incident light.

The first sub-pixel SP1 may be a red sub-pixel. In an example in which the first light emitting element LD1 emits blue light, the first light conversion pattern CCP1 may include first color conversion particles QD1 configured to convert blue light into red light. In an example in which the first light emitting element LD1 emits red light, the first light conversion pattern CCP1 may include the scattering particles. Accordingly, for example, particles included in the first light conversion pattern CCP1 may be variously changed according to the first light emitting element LD1.

The low-refractive-index layer LRL may be disposed on the second bank BNK2, the reflective layer RFL, and the first light conversion pattern CCP1. The low-refractive-index layer LRL may have a lower refractive index than the first light conversion pattern CCP1 and a first color filter CF1. The low refractive index layer LRL is configured to refract or totally reflect light according to an incident angle of the light. For example, the low refractive index layer LRL may provide the light passing through the first light conversion pattern CCP1 back to the first light conversion pattern CCP1. Accordingly, light conversion efficiency of the first light conversion pattern CCP1 may be increased.

The color filter layer CFL may be disposed on the low refractive index layer LRL. The color filter layer CFL may include the first color filter CF1 and light blocking patterns LBP. The first color filter CF1 overlaps the first light conversion pattern CCP1. The first color filter CF1 may selectively transmit light in a desired wavelength range therethrough. In an example in which the first sub-pixel SP1 is a red sub-pixel, the first color filter CF1 may include a red filter. The light blocking patterns LBP may include at least one of various types of light blocking materials.

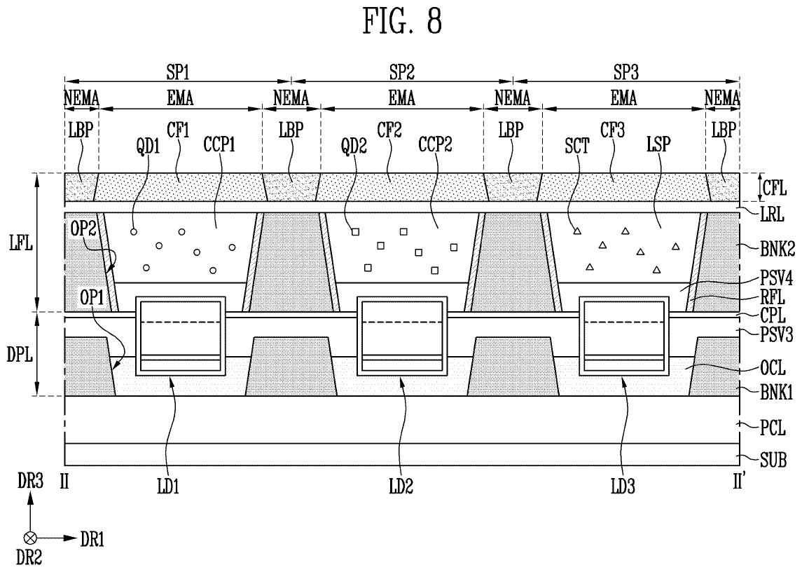

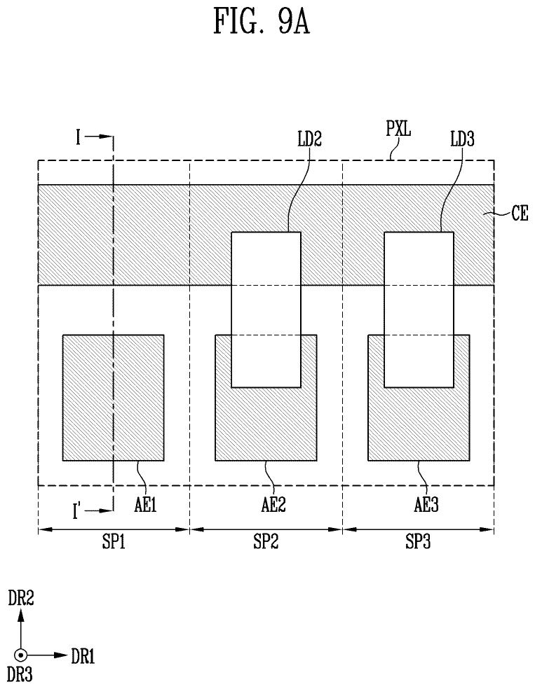

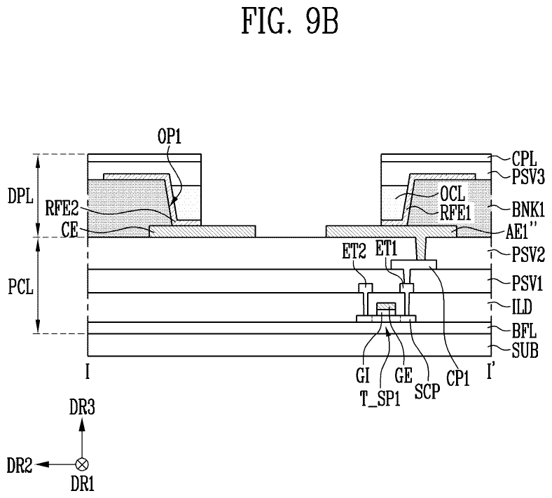

FIG. 8 is a cross-sectional view taken along line II-II′ of FIG. 6.

Referring to FIGS. 6 and 8, the pixel circuit layer PCL, the display panel layer DPL, and the light conversion layer LCL may be sequentially provided on the substrate SUB.

The pixel circuit layer PCL and the display panel layer DPL are described in the same manner as described with reference to FIG. 7. Sub-pixel circuits respectively corresponding to the first to third sub-pixels SP1 to SP3 are provided in the pixel circuit layer PCL. The first to third light emitting elements LD1 to LD3 respectively corresponding to the first to third sub-pixels SP1 to SP3 are provided in the display panel layer DPL. The first to third light emitting elements LD1 to LD3 may respectively overlap the first openings OP1 of the first bank BNK1. The first light emitting element LD1 is connected between the cathode electrode CE (see FIG. 7) and the transistor T_SP1 (see FIG. 7) included in the sub-pixel circuit of the first sub-pixel SP1. The second light emitting element LD2 is connected between the cathode electrode CE and a transistor included in a sub-pixel circuit of the second sub-pixel SP2. The third light emitting element LD3 is connected between the cathode electrode CE and a transistor included in a sub-pixel circuit of the third sub-pixel SP3. Hereinafter, duplicate descriptions are omitted.

The light conversion layer LCL is provided on the display panel layer DPL. The light conversion layer LCL is described in the same manner as described with reference to FIG. 7. Hereinafter, duplicate descriptions are omitted.

The second bank BNK2 has second openings OP2. In some aspects, a light emitting area EMA and a non-light emitting area NEMA in the first to third sub-pixels SP1 to SP3 are defined by the second bank BNK2. An area overlapping the second bank BNK2 may correspond to the non-light emitting area NEMA. Areas respectively overlapping the second openings OP2 of the second bank BNK2 may correspond to the light emitting areas EMA of the first to third sub-pixels SP1 to SP3.

The fourth passivation layer PSV4 may be disposed on the capping layer CPL within the second opening OP2. First to third light conversion patterns CCP1 to CCP3 may be disposed on the fourth passivation layers PSV4 respectively within the second openings OP2.

In embodiments, the first to third light emitting elements LD1 to LD3 may be configured to emit blue light. In this case, the first light conversion pattern CCP1 may include first color conversion particles QD1 configured to convert blue light into red light. The second light conversion pattern CCP2 may include second color conversion particles QD2 configured to convert blue light into green light. The third light conversion pattern CCP3 may include scattering particles SCT that scatter blue light to increase light emission efficiency. Accordingly, the first to third sub-pixels SP1 to SP3 may be respectively provided as a red sub-pixels, a green sub-pixel, and a blue sub-pixel. In embodiments, at least one of the first to third light conversion patterns CCP1 to CCP3 may further include color conversion particles that convert blue light into white light.

In embodiments, the first to third light emitting elements LD1 to LD3 may be configured to respectively emit red light, green light, and blue light. In this case, the first to third light conversion patterns CCP1 to CCP3 may each include the scattering particles SCT. Accordingly, for example, the particles included in the first to third light conversion patterns CCP1 to CCP3 may be variously changed according to the first to third light emitting elements LD1 to LD3.

In embodiments, the first to third light conversion patterns CCP1 to CCP3 may be omitted.

The low refractive layer LRL may be disposed on the second bank BNK2, the reflective layer RFL, and the first to third light conversion patterns CCP1 to CCP3. The low refractive layer LRL may have a lower refractive index than the first to third light conversion patterns CCP1 to CCP3 and the first to third color filters CF1 to CF3. In embodiments, the low refractive layer LRL may be omitted in an area corresponding to the third sub-pixel SP3.

The color filter layer CFL may be disposed on the low refractive layer LRL. The color filter layer CFL may include first to third color filters CF1 to CF3 and light blocking patterns (LBP).

Each of the first to third color filters CF1 to CF3 may selectively transmit light of a desired wavelength range therethrough. In an example in which the first sub-pixel SP1 is a red sub-pixel, the first color filter CF1 may include a red color filter. In an example in which the second sub-pixel SP2 is a green sub-pixel, the second color filter CF2 may include a green color filter. In an example in which the third sub-pixel SP3 is a blue sub-pixel, the third color filter CF3 may include a blue color filter.

The light blocking patterns LBP may be disposed between the first to third color filters CF1 to CF3. In some aspects, the light emitting areas EMA and the non-light emitting areas (NEMA) of the first to third sub-pixels SP1 to SP3 are defined by the light blocking patterns LBP. Areas respectively overlapping the light blocking patterns LBP may correspond to the non-light emitting areas NEMA. Areas not overlapping the light blocking patterns LBP may correspond to the light emitting areas EMA.

In embodiments, the light blocking patterns LBP may each include at least one of various types of light-blocking materials. In embodiments, each of the light blocking patterns LBP may be provided in the form of a multilayer in which at least two of the first to third color filters CF1 to CF3 overlap each other. For example, the light blocking patterns LBP may be formed by respectively overlapping the first to third color filters CF1 to CF3). In another example, the light blocking pattern LBP between the first and second color filters CF1 and CF2 may be formed as a multilayer in which the first and second color filters CF1 and CF2 overlap each other, and the light blocking pattern LBP between the second and third color filters CF2 and CF3 may be formed as a multilayer in which the second and third color filters CF2 and CF3 overlap each other. The light blocking pattern LBP between the first color filter CF1 and the third color filter CF3 of adjacent pixels may be formed as a multilayer in which the first and third color filters CF1 and CF3 overlap each other. Accordingly, for example, the first to third color filters CF1 to CF3 may each extend to the non-light emitting area NEMA to form the light blocking patterns LBP.

A manufacturing process of a display device may include a process of testing light emitting elements included in a display panel. For example, the first light emitting element LD1 may be tested immediately after the first light emitting element LD1 is connected to the first and second reflective electrodes RFE1 and RFE2 through the first and second bonding electrodes BDE1 and BDE2. In this case, the first light emitting element LD1 may be tested while the display panel layer DPL is formed and the light conversion layer LCL is not formed. In another example, the first light emitting element LD1 may also be tested after the light conversion layer LCL is formed.

In some cases, when a defect occurs in the first light emitting element LD1, it may be desired or be necessary to remove the first light emitting element LD1 and to provide another light emitting element. Hereinafter, a process, in which a new light emitting element is disposed when a defect occurs in the first light emitting element LD1, will be described.

FIG. 9A is a plan view illustrating a pixel from which one defective light emitting element is removed. FIG. 9B is a cross-sectional view taken along line I-I′ of FIG. 9A.

Referring to FIGS. 9A and 9B together, a defect occurs in the first light emitting element LD1, and accordingly, the first light emitting element LD1 is removed during a process. Referring to FIG. 9B, an embodiment is illustrated in which the first light emitting element LD1 is removed in a state where the display panel layer DPL is formed and the light conversion layer LCL is not formed.

Specifically, the first light emitting element LD1 is removed by a laser. In this case, a part of the overcoat layer OCL, a part of each of the first and second bonding electrodes BDE1 and BDE2, and a part of each of the first and second reflective electrodes RFE1 and RFE2 near the first light emitting element LD1 may be removed. In some embodiments, the first and second reflective electrodes RFE1 and RFE2 may not be removed.

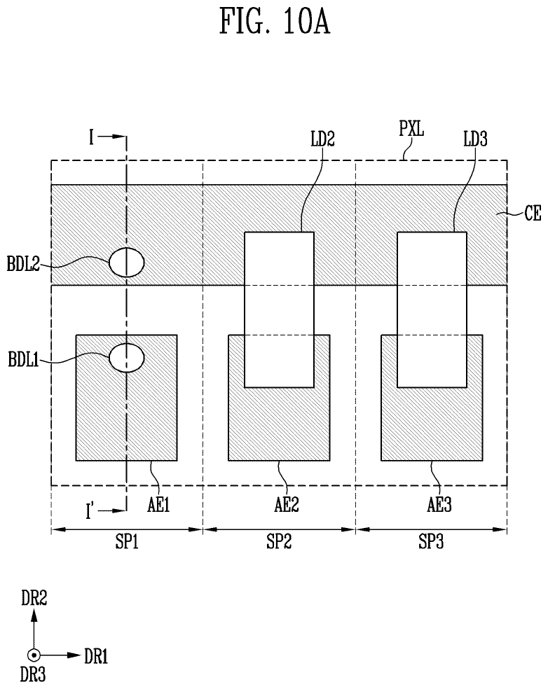

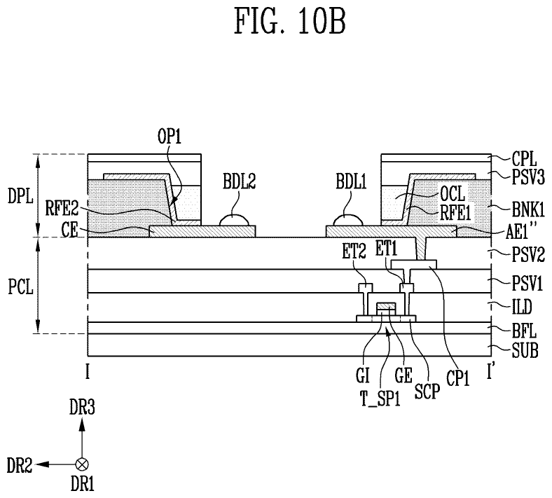

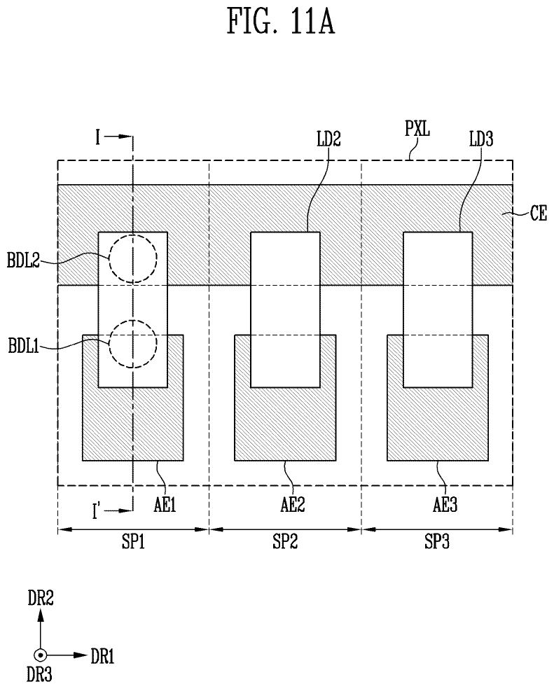

FIG. 10A is a plan view illustrating a process of disposing a conductive material on an anode electrode and a cathode electrode after a light emitting element is removed. FIG. 10B is a cross-sectional view taken along line I-I′ of FIG. 10A.

Referring to FIG. 10A and FIG. 10B together, the process is performed after the first light emitting element LD1 is removed. A first bonding material BDL1 and a second bonding material BDL2 may be respectively disposed on the first anode electrode AE1 and the cathode electrode CE. In an embodiment, the first and second bonding materials BDL1 and BDL2 may be conductive materials in a liquid state. In some embodiments, the first and second bonding materials BDL1 and BDL2 may be respectively sprayed onto the first anode electrode AE1 and the cathode electrode CE by using an inkjet method.

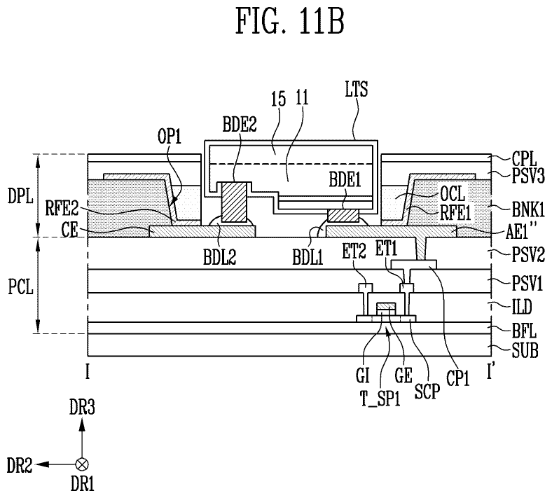

FIG. 11A is a plan view illustrating a process of connecting a light emitting element to an anode electrode and a cathode electrode through a conductive material. FIG. 11B is a cross-sectional view taken along line I-I′ of FIG. 11A.

Referring to FIGS. 11A and 11B, the first light emitting element LD1, which is a new light emitting element, may be disposed on the first anode electrode AE1 and the cathode electrode CE in a state where the first bonding material BDL1 and the second bonding material BDL2 are disposed. In this case, the first light emitting element LD1 may be aligned such that first and second bonding electrodes BDE1 and BDE2 of the first light emitting element LD1 are respectively connected to the first anode electrode AE1 and the cathode electrode CE respectively through the first and second bonding materials BDL1 and BDL2 After the first light emitting element LD1 is aligned, by applying a predetermined pressure to the first light emitting element LD1 in a direction opposite to the third direction DR3, the first and second bonding electrodes BDE1 and BDE2 of the first light emitting element LD1 may be respectively connected to the first anode electrode AE1 and the cathode electrode CE respectively through the first and second bonding materials BDL1 and BDL2. In this process, the first and second bonding materials BDL1 and BDL2 in a liquid state may spread, and some of the first and second bonding materials BDL1 and BDL2 may overflow outside the first anode electrode AE1 and the cathode electrode CE. Referring to FIGS. 11A and 11B, it can be seen that a part of the first bonding material BDL1 on the first anode electrode AE1 overflows toward the cathode electrode CE.

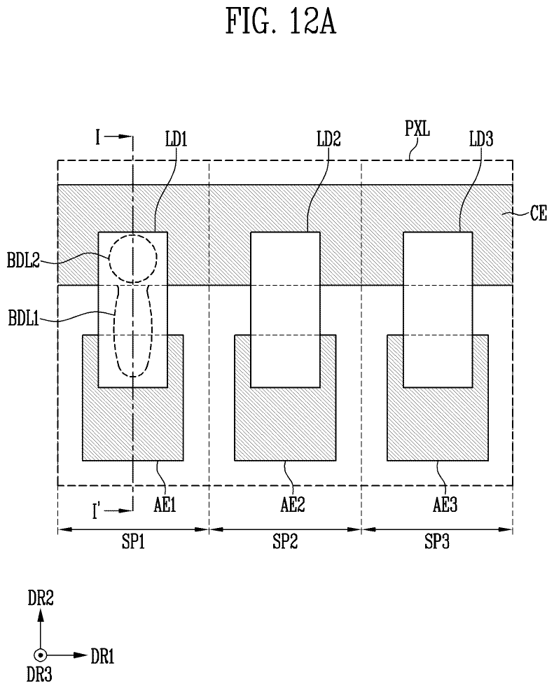

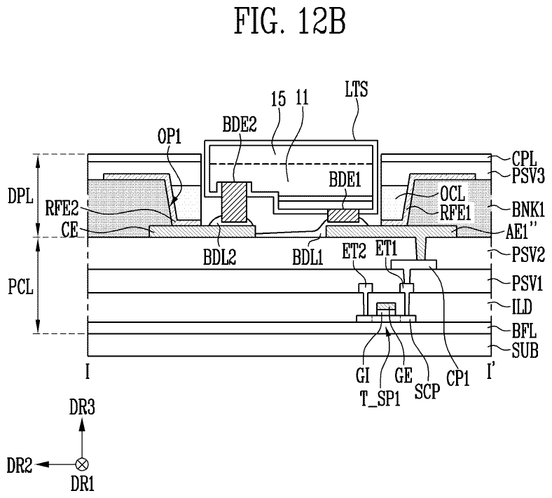

FIG. 12A is a plan view illustrating a phenomenon in which a conductive material overflows and the first anode electrode AE1 and the cathode electrode CE are short-circuited. FIG. 12B is a cross-sectional view taken along line I-I′ of FIG. 12A.

As illustrated in FIGS. 11A and 11B, even when a part of the first bonding material BDL1 on the first anode electrode AE1 overflows toward the cathode electrode CE, when the first bonding material BDL1 does not reach the cathode electrode CE, there may be no problem in an operation of the first light emitting element LD1. However, as illustrated in FIG. 11A and FIG. 12B, when a part of the first bonding material BDL1 on the first anode electrode AE1 reaches the cathode electrode CE, the first anode electrode AE1 and the cathode electrode CE of the first light emitting element LD1 are short-circuited to each other.

This problem may occur due to various causes. For example, the lower the viscosity of the first bonding material BDL1, the higher the possibility that the first bonding material BDL1 overflows and reaches the cathode electrode CE when a predetermined pressure is applied to a first light emitting element in a direction opposite to the third direction DR3. Alternatively, even when a large amount of the first bonding material BDL1 is disposed on the first anode electrode AE1, the possibility increases that the first bonding material BDL1 overflows and reaches the cathode electrode CE when connecting the first light emitting element LD1. In some embodiments, as the resolution of a display panel increases, even when a distance between the first anode electrode AE1 and the cathode electrode CE is reduced, the possibility increases that the first bonding material BDL1 overflows and reaches the cathode electrode CE when connecting the first light emitting element LD1.

The problem that a part of the first bonding material BDL1 on the first anode electrode AE1 reaches the cathode electrode CE is described with reference to FIGS. 12A and 12B. In contrast to this, the same problem may occur when a part of the second bonding material BDL2 on the cathode electrode CE reaches the first anode electrode AE1.

According to the embodiment of the present disclosure, an overflow prevention pattern is formed on an anode electrode or a cathode electrode connected to a light emitting element. A short circuit between electrodes, which is caused by a bonding material during a process of connecting a light emitting element to an anode electrode and a cathode electrode by using a liquid-state bonding material, is prevented by the overflow prevention pattern.

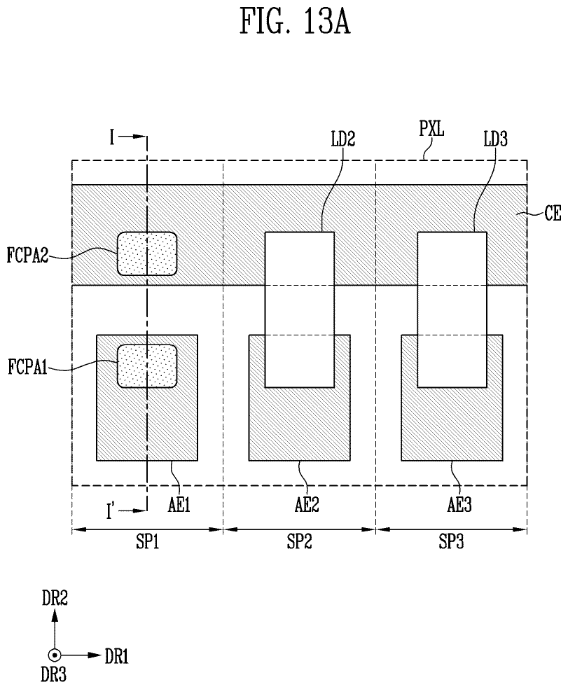

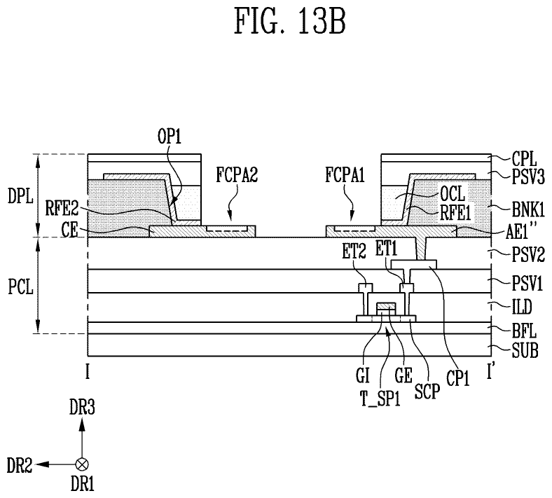

FIG. 13A is a plan view illustrating an embodiment of the present disclosure in which an overflow prevention pattern is formed on an anode electrode and a cathode electrode. FIG. 13B is a cross-sectional view taken along line I-I′ of FIG. 13A.

Referring to FIGS. 13A and 13B, a pixel from which a first light emitting element LD1 is removed is illustrated, similarly to FIG. 9A. In some embodiments, referring to FIG. 13A, a first overflow prevention pattern area FCPA1 and a second overflow prevention pattern area FCPA2 are formed respectively on the first anode electrode AE1 and the cathode electrode CE. In each of the first and second overflow prevention pattern areas FCPA1 and FCPA2, an overflow prevention pattern may be formed which may prevent a liquid-state bonding material from overflowing or control a direction of overflow of the bonding material. For example, an overflow prevention pattern formed in the first overflow prevention pattern area FCPA1 of the first anode electrode AE1 may prevent the liquid-state first bonding material from reaching (i.e., from overflowing to) the cathode electrode CE. In some embodiments, an overflow prevention pattern formed in the second overflow prevention pattern area FCPA2 of the cathode electrode CE may prevent the liquid-state second bonding material from reaching (i.e., from overflowing to) the first anode electrode AE1.

Hereinafter, the overflow prevention pattern formed in the first overflow prevention pattern area FCPA1 of the first anode electrode AE1 will be mainly described. However, it is to be understood that aspects of the overflow prevention pattern formed in the second overflow prevention pattern area FCPA2 of the cathode electrode CE may similarly be applied to the overflow prevention pattern formed in the first overflow prevention pattern area FCPA1 of the first anode electrode AE1.

In some embodiments, the bonding material described herein may be a conductive material.

Embodiments of the present disclosure may include respectively forming the overflow prevention patterns, through laser processing, on the first anode electrode AE1 and the cathode electrode CE in a state where the first light emitting element LD1 is removed. In some aspects, the overflow prevention patterns respectively formed on the first anode electrode AE1 and the cathode electrode CE may be engraved patterns each having a predetermined depth.

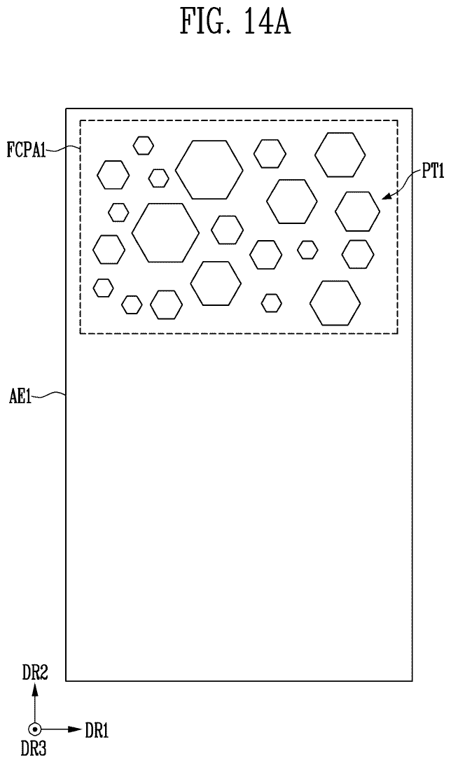

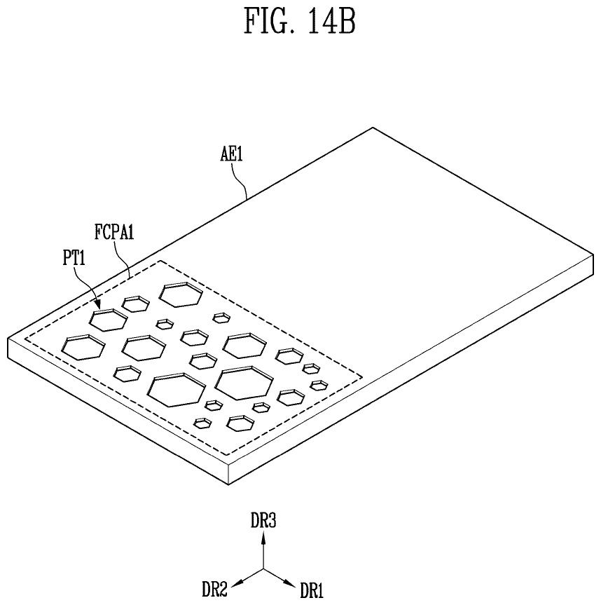

FIG. 14A is a plan view illustrating an embodiment of the overflow prevention pattern. FIG. 14B is a perspective view illustrating an embodiment of the overflow prevention pattern.

Referring to FIGS. 14A and 14B, hexagonal overflow prevention patterns PT1 may be formed in the first overflow prevention pattern area FCPA1 of the first anode electrode AE1. However, embodiments of the present disclosure are not limited thereto, and the overflow prevention patterns may each have a shape of, for example, a triangle, a square, a circle, a circular pattern, an ellipse, an elliptical pattern, a polygon, a polygonal pattern, or the like and be formed in the first overflow prevention pattern area FCPA1 of the first anode electrode AE1. In an embodiment, as illustrated in FIGS. 14A and 14B, the patterns formed in the first overflow prevention pattern area FCPA1 may have the same hexagonal shape, but embodiments of the present disclosure are not limited thereto. For example, patterns of different shapes, such as, for example, circles, ovals, hexagons, squares, other polygons, or the like may be formed together in the first overflow prevention pattern area FCPA1.

In some embodiments, although FIGS. 14A and 14B illustrate hexagonal patterns having various sizes, embodiments of the present disclosure are not limited thereto. In some embodiments, the patterns formed in the first overflow prevention pattern area FCPA1 may have the same size.

As illustrated in FIGS. 14A and 14B, by forming an overflow prevention pattern on the first anode electrode AE1, the first bonding material BDL1 disposed on the first anode electrode AE1 is preferentially accommodated in the overflow prevention pattern when pressure is applied to a light emitting element in association with connecting the light emitting element to the first anode electrode AE1 and the cathode electrode CE. Accordingly, the phenomenon, in which the first bonding material BDL1 reaches the cathode electrode CE and causes a short-circuit between the first anode electrode AE1 and the cathode electrode CE, may be prevented.

FIG. 15A is a plan view illustrating another embodiment of an overflow prevention pattern. FIG. 15Bb is a perspective view illustrating the embodiment of the overflow prevention pattern of FIG. 15A.

Referring to FIGS. 15A and 15B, a plurality of overflow prevention patterns PT2, each having a stripe shape with a constant depth, may be formed in the first overflow prevention pattern area FCPA1 of the first anode electrode AE1. The plurality of overflow prevention patterns PT2 of a stripe shape extend in the first direction DR1. In some aspects, the plurality of overflow prevention patterns PT2 are repeatedly disposed in the second direction DR2 perpendicular to the first direction DR1. The plurality of overflow prevention patterns PT2 of a stripe shape may be referred to as stripe-shaped patterns.

As illustrated in FIGS. 15A and 15B, an extension direction of the plurality of overflow prevention patterns PT2 of a stripe shape may be the first direction DR1. The extension direction of the plurality of overflow prevention patterns PT2 may be substantially the same as an extension direction of the cathode electrode CE. Since the extension direction of the plurality of overflow prevention patterns PT2 is the first direction DR1, when pressure is applied to a light emitting element in association with connecting the light emitting element to an anode electrode and a cathode electrode, movement of the first bonding material BDL1 in the second direction DR2 is suppressed, and movement in the first direction DR1 or in a direction opposite to the first direction DR1 is induced. Accordingly, a phenomenon, in which the first bonding material BDL1 reaches the cathode electrode CE and causes a short-circuit between the first anode electrode AE1 and the cathode electrode CE, may be prevented.

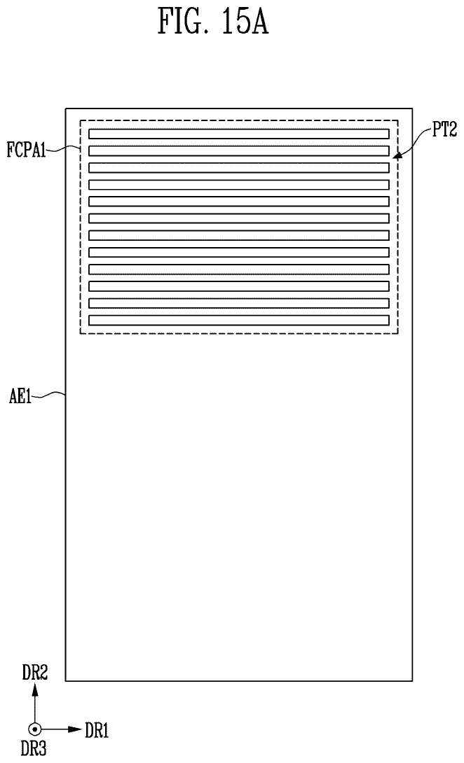

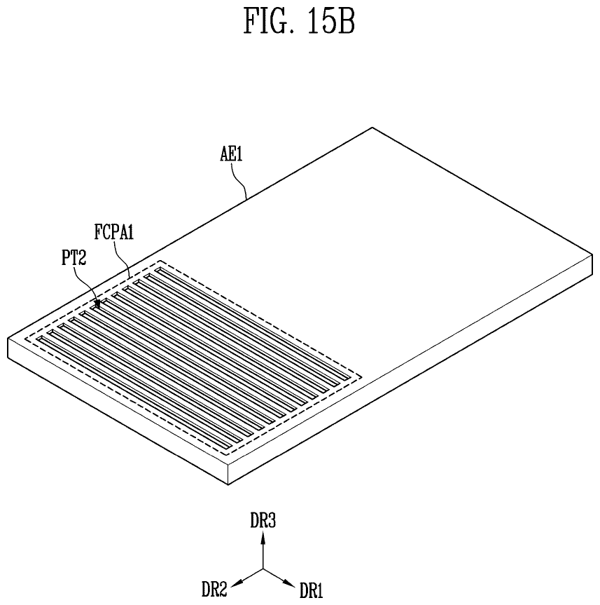

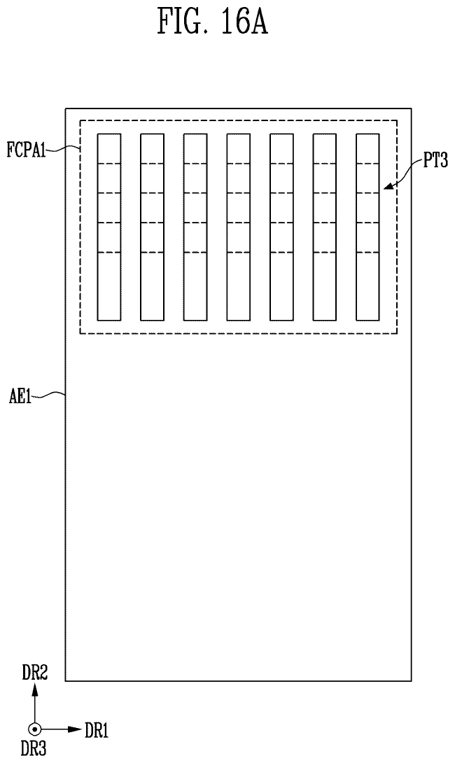

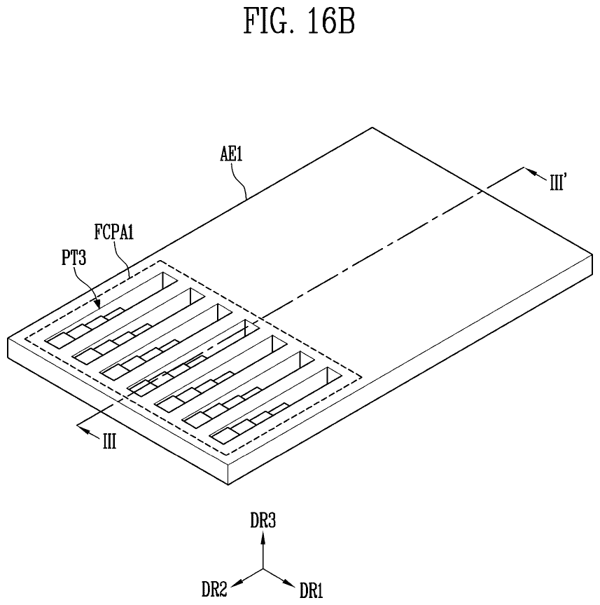

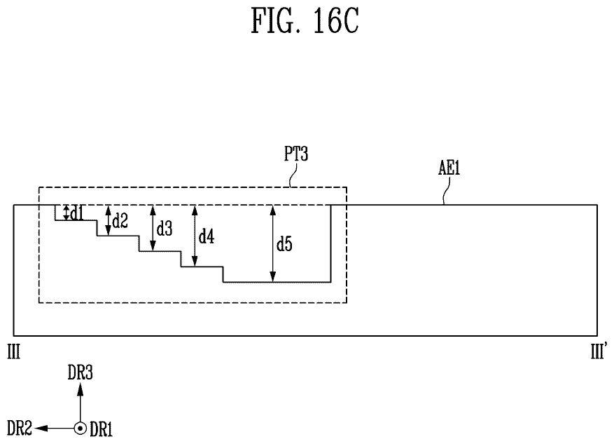

FIG. 16A is a plan view illustrating another embodiment of the overflow prevention pattern. FIG. 16B is a perspective view illustrating the embodiment of the overflow prevention pattern of FIG. 16A. FIG. 16C is a cross-sectional view taken along line III-III′ of FIG. 16B.

Referring to FIGS. 16A, 16B, and 16C, an overflow prevention pattern PT3 of a stripe shape may be formed in the first overflow prevention pattern area FCPA1 of the first anode electrode AE1. For example, a plurality of overflow prevention patterns PT3 of a stripe shape may be formed in the first overflow prevention pattern area FCPA1 of the first anode electrode AE1. As illustrated in FIGS. 16A and 16B, an extension direction of the overflow prevention pattern PT3 of a stripe shape may be the second direction DR2. Since the extension direction of the overflow prevention pattern PT3 is the second direction DR2, when pressure is applied to a light emitting element in association with connecting the light emitting element to an anode electrode and a cathode electrode CE, movement of the first bonding material BDL1 in the first direction DR1 or in a direction opposite to the first direction DR1 may be suppressed, and movement in the second direction DR2 or in a direction opposite to the second direction DR2 may be induced.

In some embodiments, as illustrated in FIGS. 16A, 16B, and 16C, the overflow prevention pattern PT3 may include a step shape. That is, a bottom surface of the overflow prevention pattern PT3 may be of varied depths (i.e., the bottom surface may not be a surface having a constant depth). For example, the bottom surface may be formed in a step shape having different depths. Expressed another way, the overflow prevention pattern PT3 may include a stepped portion including multiple bottom surfaces, and the bottom surfaces may be disposed in the second direction DR2 and have different respective depths.

Referring to FIG. 16C, a first bottom surface of the overflow prevention pattern PT3 has a first depth d1, a second bottom surface of the overflow prevention pattern PT3 has a second depth d2 greater than the first depth d1, a third bottom surface of the overflow prevention pattern PT3 has a third depth d3 greater than the second depth d2, a fourth bottom surface of the overflow prevention pattern PT3 has a fourth depth d4 greater than the third depth d3, and a fifth bottom surface of the overflow prevention pattern PT3 has a fifth depth d5 greater than the fourth depth d4. Although FIGS. 16A, 16B, and 16C illustrate that the overflow prevention pattern PT3 has five bottom surfaces, embodiments of the present disclosure are not limited thereto. The number of bottom surfaces of the overflow prevention pattern PT3 and the depth of each bottom surface may be determined variously as applicable (e.g., based on one or more target criteria).

Referring to FIGS. 16A, 16B, and 16C, the farther away from the cathode electrode CE, the deeper the bottom depth of the overflow prevention pattern PT3. That is, the bottom depth of the overflow prevention pattern PT3 increase as the overflow prevention pattern PT3 proceeds in a direction opposite to the second direction DR2. Expressed another way, in each overflow prevention pattern PT3, the respective depths (e.g., d1, d2, d3, and the like) of the plurality of bottom surfaces may increase in a direction away from the cathode electrode CE.

Accordingly, when pressure is applied to a light emitting element in association with connecting the light emitting element to an anode electrode and a cathode electrode, movement in the second direction DR2 may be suppressed, and movement in a direction opposite to the second direction DR2 may be induced. Accordingly, a phenomenon, in which the first bonding material BDL1 reaches the cathode electrode CE and causes a short-circuit between the first anode electrode AE1 and the cathode electrode CE, may be prevented.

FIG. 17 is a plan view illustrating another embodiment of an overflow prevention pattern.

Referring to FIG. 17, an overflow prevention pattern PT4 having a trapezoidal shape may be formed in the first overflow prevention pattern area FCPA1 of the first anode electrode AE1. For example, a plurality of overflow prevention patterns PT4 having a trapezoidal shape may be formed in the first overflow prevention pattern area FCPA1 of the first anode electrode AE1. As illustrated in FIG. 17, an extension direction of the overflow prevention pattern PT4 having a trapezoidal shape may be the second direction DR2. Since the extension direction of the overflow prevention pattern PT4 is the second direction DR2, when pressure is applied to a light emitting element in association with connecting the light emitting element to an anode electrode and a cathode electrode, movement of the first bonding material BDL1 in the first direction DR1 or in a direction opposite to the first direction DR1 may be suppressed, and movement of the first bonding material BDL1 in the second direction DR2 or in a direction opposite to the second direction DR2 may be induced.

In some embodiments, as illustrated in FIG. 17, a pattern width of the overflow prevention pattern PT4 may increase as the overflow prevention pattern PT4 is far away from the cathode electrode CE. That is, the pattern width of the overflow prevention pattern PT4 may increase as the overflow prevention pattern PT4 proceeds in a direction opposite to the second direction DR2. Expressed another way, widths of each overflow prevention pattern PT4 may increase in a direction away from the cathode electrode CE.

Accordingly, when pressure is applied to a light emitting element in association with connecting the light emitting element to an anode electrode and a cathode electrode, movement of the first bonding material BDL1 in the second direction DR2 may be suppressed, and movement of the first bonding material BDL1 in a direction opposite to the second direction DR2 may be induced. Accordingly, a phenomenon in which the first bonding material BDL1 reaches the cathode electrode CE and causes a short-circuit between the first anode electrode AE1 and the cathode electrode CE, may be prevented.

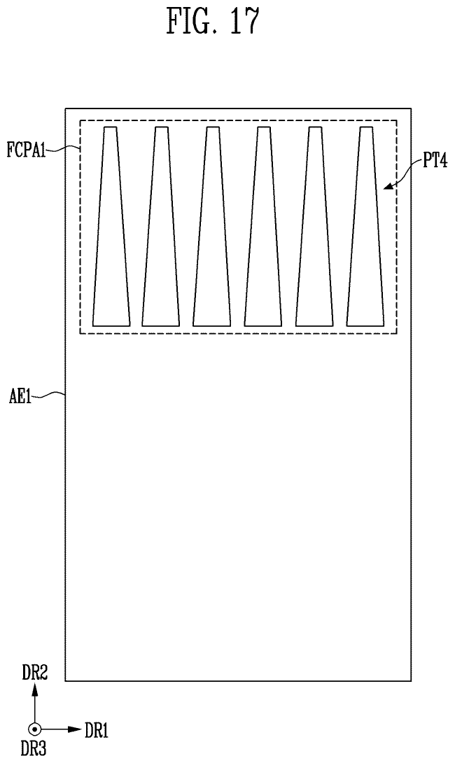

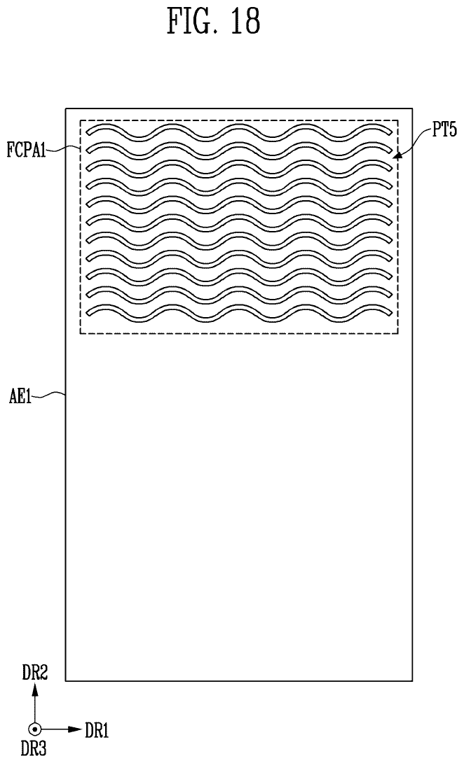

FIG. 18 is a plan view illustrating another embodiment of an overflow prevention pattern.

Referring to FIG. 18, an overflow prevention pattern PT5 having a shape of a wave pattern is repeated at regular intervals may be formed in the first overflow prevention pattern area FCPA1 of the first anode electrode AE1. Expressed another way, a plurality of overflow prevention patterns PT5 (also referred to herein as wave-shaped patterns) may be formed in the first overflow prevention pattern area FCPA1 of the first anode electrode AE1. As illustrated in FIG. 18, an extension direction of the overflow prevention pattern PT5 may be the first direction DR1. The extension direction of the overflow prevention pattern PT5 may be substantially the same as an extension direction of the cathode electrode CE. Since the extension direction of the overflow prevention pattern PT5 is the first direction DR1, when pressure is applied to a light emitting element in association with connecting the light emitting element to an anode electrode and a cathode electrode, movement of the first bonding material BDL1 in the second direction DR2 is suppressed, and movement of the first bonding material BDL1 in the first direction DR1 or a direction opposite to the first direction DR1 is induced. Accordingly, a phenomenon, in which the first bonding material BDL1 reaches the cathode electrode CE and causes a short-circuit between the first anode electrode AE1 and the cathode electrode CE, may be prevented.

Example aspects of a method and processes supported by aspects of the present disclosure are described with reference to the following figures. In the descriptions of the method and processes herein, the operations may be performed in a different order than the order shown and/or described, or the operations may be performed in different orders or at different times. Certain operations may also be left out of the flowcharts, one or more operations may be repeated, or other operations may be added. Descriptions that an element “may be disposed,” “may be formed,” and the like include methods, processes, and techniques for disposing, forming, positioning, and modifying the element, and the like in accordance with example aspects described herein.

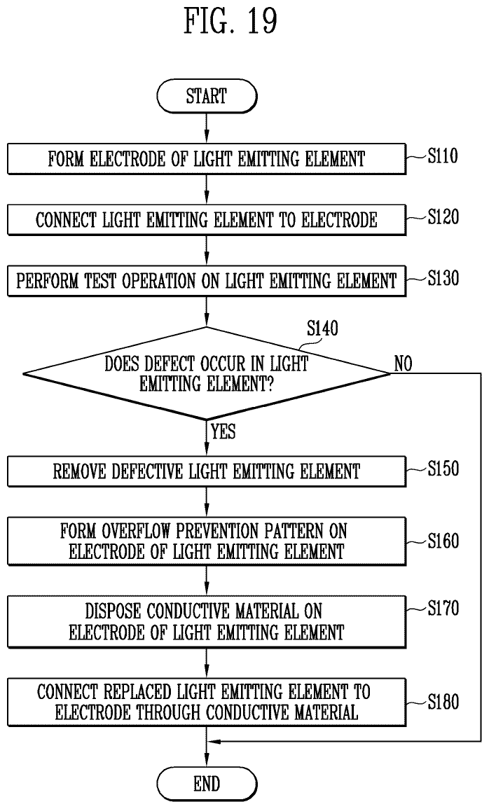

FIG. 19 is a flowchart illustrating a method of manufacturing a display device, according to an embodiment of the present disclosure.

Referring to FIG. 19, the method of manufacturing a display device, according to the embodiment of the present disclosure includes step S110 of forming an electrode of a light emitting element, step S120 of connecting the light emitting element to the electrode, step S130 of performing a test operation on the light emitting element, step S140 of determining whether a defect occurs in the light emitting element, step S150 of removing a defective light emitting element based on determining, at least in part from performing the test operation, a defect has occurred in the light emitting element (e.g., when a defect occurs in the light emitting element), step S160 of forming an overflow prevention pattern on the electrode of the light emitting element, step S170 of disposing a conductive material on the electrode of the light emitting element, and step S180 of connecting a replacement light emitting element to the electrode through the conductive material.

The method may include, in step S110 of forming the electrode of the light emitting element, forming an anode electrode and a cathode electrode. Thereafter, for example, in step S120, the method may include respectively connecting the first bonding electrode BDE1 and the second bonding electrode BDE2 of the light emitting element to an anode electrode and a cathode electrode (or the first and second reflective electrodes RFE1 and RFE2). Thereafter, for example, the method may include performing a test operation on the connected light emitting element (S130).

In an example, based on a test result indicating that no defect occurs in the light emitting element (S140: No), the method may include refraining from performing steps S150, S160, S170, and S180. In some examples, the method may include performing other subsequent processes after S140.

In another example, based on a test result indicating that a defect occurs in the light emitting element (S140: Yes), the method may include removing the defective light emitting element (S150). In some examples, at step S150, the method may include removing the first light emitting element LD1 by using a laser. In this case, for example, the method may include partially removing the overcoat layer OCL, the bonding electrodes BDE1 and BDE2, and the reflective electrodes RFE1 and RFE2 near the first light emitting element LD1. In some embodiments, the reflective electrodes RFE1 and RFE2 may not be removed.

In subsequent step S160, the method may include forming an overflow prevention pattern on the electrode of the light emitting element. In step S160, the method may include forming the overflow prevention pattern on at least one of the anode electrode and the cathode electrode. In this case, for example, the overflow prevention pattern according to various embodiments described with reference to FIGS. 14A to 18 may be formed on the anode electrode or the cathode electrode.

Thereafter, in step S170, the method may include disposing a conductive material on the electrode of the light emitting element. The conductive material described in step S170 may be at least one of the first and second bonding materials BDL1, BDL2 in a liquid state.

Thereafter, in step S180, the method may include connecting the replacement light emitting element to the anode electrode and the cathode electrode through the conductive material. In some aspects, while performing step S180, the method may include applying a constant pressure to the light emitting element. In this process, a short circuit between the electrodes may be prevented by the overflow prevention pattern and the conductive material.

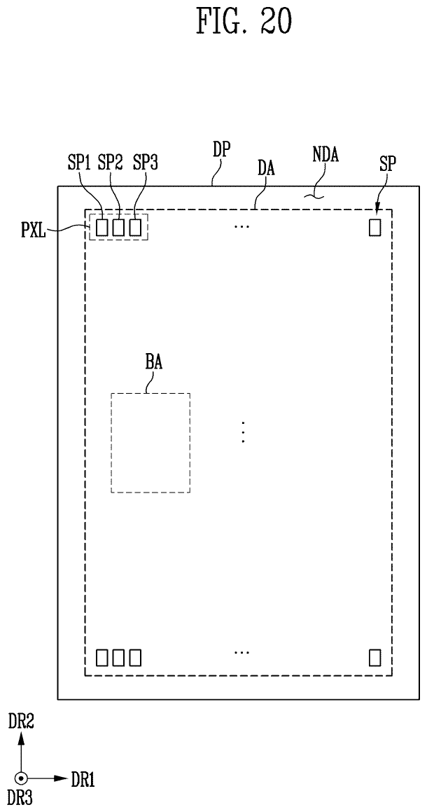

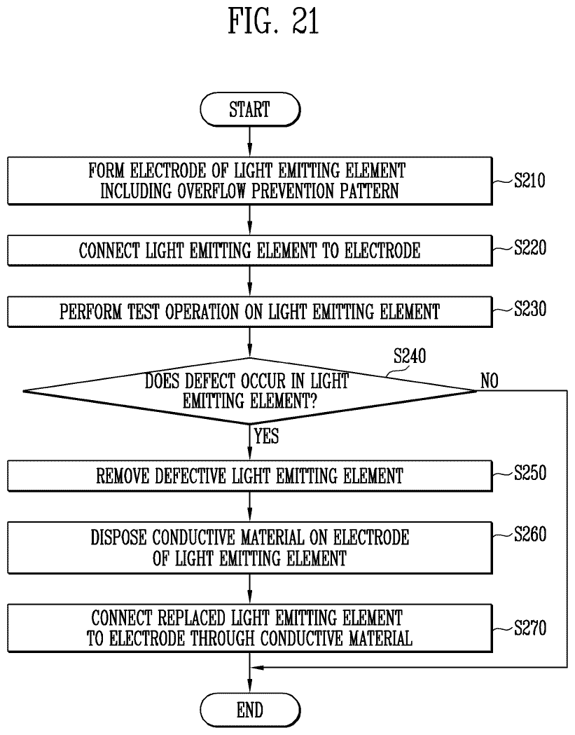

Referring to FIG. 19, an embodiment is illustrated in which the method includes selectively forming an overflow prevention pattern on electrodes corresponding to a light emitting element determined as having a defect as a result of performing the test operation on the light emitting element. However, embodiments of the present disclosure are not limited thereto, and the method may include forming an overflow prevention pattern in advance on electrodes before the test operation is performed. For example, in some embodiments, the method may include forming an overflow prevention pattern in advance on electrodes corresponding to areas where defects frequently occur. Hereinafter, description will be made with reference to FIG. 20 and FIG. 21.

FIG. 20 is a plan view illustrating a defective area of a display panel.

Referring to FIG. 20, a display panel DP may include a display area DA and a non-display area NDA. The display panel DP displays an image through the display area DA. The non-display area NDA is disposed around the display area DA. In describing FIG. 20, descriptions duplicated with respect to FIG. 3 will be omitted.

The display area DA may include a defective area BA. The defective area BA may be an area corresponding to pixels PXL that have a high probability of occurrence of a defect compared to other areas. The defective area BA may be empirically set based on test results of a plurality of display panels DP.

According to an embodiment of the present disclosure, during a manufacturing process of the display area DA, the manufacturing process may include forming an overflow prevention pattern in advance on cathode electrodes or anode electrodes included in the defective area BA.

However, this is an example and embodiments of the present disclosure are not limited thereto. According to an embodiment, instead of separately setting the defective area BA, the manufacturing process may include forming an overflow prevention pattern on cathode electrodes or anode electrodes included in each of all pixels included in the display panel DP.

FIG. 21 is a flowchart illustrating a method of manufacturing a display device, according to another embodiment of the present disclosure.

Referring to FIG. 21, the method of manufacturing a display device, according to the embodiment of the present disclosure includes step S210 of forming an electrode of a light emitting element which includes an overflow prevention pattern, step S220 of connecting the light emitting element to the electrode, step S230 of performing a test operation on the light emitting element, step S240 of determining whether a defect occurs in the light emitting element, step S250 of removing a defective light emitting element based on determining, at least in part from performing the test operation, a defect has occurred in the light emitting element (e.g., when a defect occurs in the light emitting element), step S260 of disposing a conductive material on the electrode of the light emitting element, and step S270 of connecting a replacement light emitting element to the electrode through the conductive material.

The method may include, in step S210, forming the overflow prevention pattern on an anode electrode or a cathode electrode located within the defective area BA as illustrated in FIG. 20. In some embodiments, the overflow prevention pattern may not be formed on an anode electrode or a cathode electrode outside the defective area BA. However, embodiments of the present disclosure are not limited thereto, and in some examples, in step S210, the method may include forming the overflow prevention pattern on all anode electrodes or cathode electrodes in a display panel.

Thereafter, for example, the method may include respectively connecting the first and second bonding electrodes BDE1 and BDE2 of the light emitting element to the anode electrode and the cathode electrode (or the first and second reflective electrodes RFE1 and RFE2) (S220). Thereafter, for example, the method may include performing a test operation on the connected light emitting element (S230).

In an example, based on a test result indicating there is no defect in the light emitting element (S240: No), the method may include refraining from performing steps S250, S260, and S270. In some examples, the method may include performing other subsequent processes after S240.

In another example, based on a test result indicating there is a defect in the light emitting element (S240: Yes), the method may include removing the defective light emitting element (S250). In some examples, at step S250, the method may include removing the first light emitting element LD1 by a laser. In this case, for example, the method may include partially removing the overcoat layer OCL, the first and second bonding electrodes BDE1 and BDE2, and the first and second reflective electrodes RFE1 and RFE2 near the first light emitting element LD1. In some embodiments, the first and second reflective electrodes RFE1 and RFE2 may not be removed. In this process, the overflow prevention pattern formed on the electrode may be exposed.

In a subsequent step S260, the method may include disposing a conductive material on the electrode of the light emitting element. The conductive material described in step S260 may be at least one of the first and second bonding materials BDL1 and BDL2 in a liquid state.

In a subsequent step S270, the method may include connecting the replacement light emitting element to the anode electrode and the cathode electrode through the conductive material. In some aspects, while performing step S270, the method may include applying a constant pressure to the light emitting element. In this process, a short circuit between the electrodes may be prevented by the overflow prevention pattern and the conductive material.

As described herein, preventing a short circuit between the anode electrode and the cathode electrode through the overflow prevention pattern is described as one effect of the present disclosure. However, effects of the present disclosure are not limited thereto. In another utility of the overflow prevention pattern, a frictional force of a newly attached light emitting element is increased due to a fixing force. The overflow prevention pattern may increase a frictional force between the first and second bonding electrodes BDE1 and BDE2 of the newly attached light emitting element and at least one of the anode and cathode electrodes. Accordingly, the first and second bonding electrodes BDE1 and BDE2 of the light emitting element may be more strongly attached to the anode and cathode electrodes, and thus, the fixing force of a light emitting element is increased.

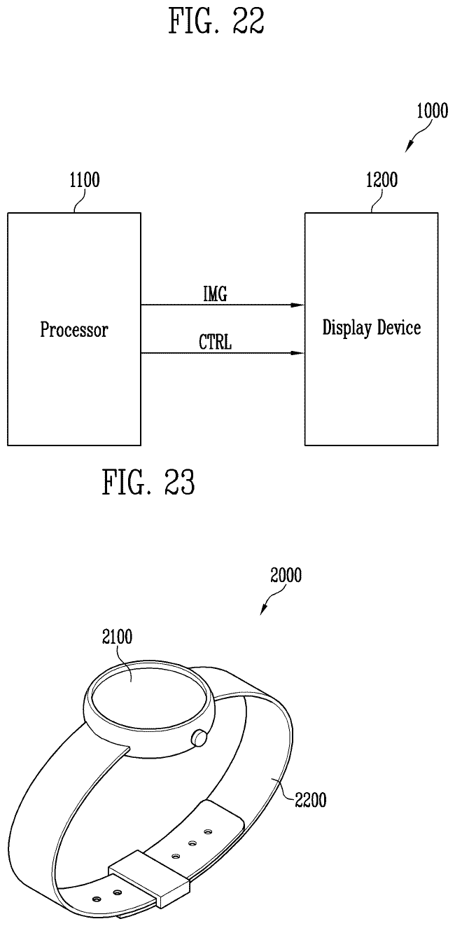

FIG. 22 is a block diagram illustrating an embodiment of a display system.

Referring to FIG. 22, a display system 1000 may include a processor 1100 and a display device 1200.

The processor 1100 may perform various tasks and calculations. In embodiments, the processor 1100 may include an application processor, a graphic processor, a microprocessor, a central processing unit (CPU), and the like. The processor 1100 may be connected to other components of the display system 1000 through a bus system and may control the other components.

The processor 1100 may transmit image data IMG and a control signal CTRL to the display device 1200. The display device 1200 may display an image based on the image data IMG and the control signal CTRL. The display device 1200 may be configured similarly to the display device DD described with reference to FIG. 1. In this case, the image data IMG and the control signal CTRL may be respectively provided as the input image data IMG and the control signal CTRL of FIG. 1.

The display system 1000 may include a computing system that provides an image display function, such as, for example, a smart watch, a mobile phone, a smartphone, a portable computer, a tablet personal computer, a watch phone, an automotive display, a smart glass, a portable multimedia player (PMP), a navigation system, and an ultramobile personal computer (UMPC). In some aspects, the display system 1000 may include at least one of a head mounted display (HMD), a virtual reality (VR) device, a mixed reality (MR) device, and an augmented reality (AR) device.

FIGS. 23 to 26 are perspective views illustrating application examples of the display system 1000 of FIG. 22.

Referring to FIG. 23, the display system 1000 of FIG. 22 may be applied to a smart watch 2000 including a display unit 2100 and a strap unit 2200.

The smart watch 2000 may be a wearable electronic device. For example, the smart watch 2000 may have a structure in which the strap unit 2200 is mounted on a user's wrist. Here, the display system 1000 and/or the display device 1200 may be applied to the display unit 2100 such that image data including time information may be provided to a user.

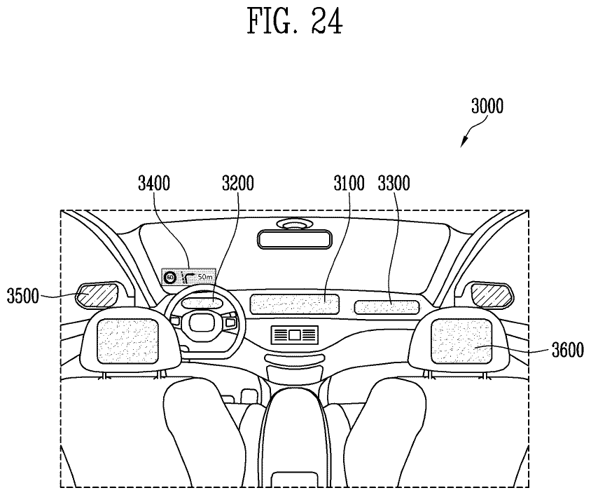

Referring to FIG. 24, the display system 1000 of FIG. 22 may be applied to an automotive display system 3000. Here, the automotive display system 3000 may include a computing system that is provided inside and/or outside a vehicle and provides image data.

For example, the display system 1000 and/or the display device 1200 may be applied to at least one of an infotainment panel 3100, a cluster 3200, a co-driver display 3300, a head-up display 3400, a side mirror display 3500, and a rear seat display 3600, which are provided in a vehicle.

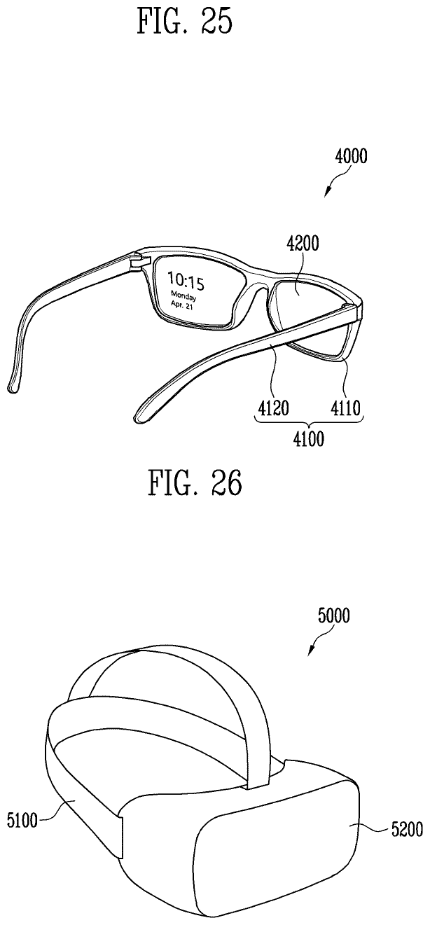

Referring to FIG. 25, the display system 1000 of FIG. 22 may be applied to smart glasses 4000. The smart glasses 4000 may be a wearable electronic device that may be worn on a user's head. For example, the smart glasses 4000 may be a wearable device for AR.

The smart glasses 4000 may include a frame 4100 and a lens unit 4200. The frame 4100 may include a housing 4110 that supports the lens unit 4200 and a leg 4120 for wearing by a user. The leg 4120 may be connected to the housing 4110 through a hinge and may be folded or unfolded with respect to the housing 4110.

The frame 4100 may include a battery, a touch pad, a microphone, a camera, and the like. In some aspects, the frame 4100 may include a projector that outputs light, a processor that controls a light signal, and the like.

The lens unit 4200 may include an optical member that transmits light therethrough or reflects light. For example, the lens unit 4200 may include glass, a transparent synthetic resin, and the like.

In order for a user's eyes to recognize visual information, a rear surface (for example, a surface facing a user's eyes) of the lens unit 4200 may reflect an image according to a light signal transmitted from a projector of the frame 4100. For example, a user may recognize visual information, such as, for example, time and date displayed on the lens unit 4200. In this case, the projector and/or the lens unit 4200 may be a type of display device. The display device 1200 may be applied to the projector and/or the lens unit 4200.

Referring to FIG. 26, the display system 1000 of FIG. 22 may be applied to a head-mounted display device 500.

The head-mounted display device 5000 may be a wearable electronic device that may be worn on a user's head. For example, the head-mounted display device 5000 may be a wearable device for VR or MR.

The head-mounted display device 5000 may include a head-mounted band 5100 and a display device storage case 5200. The head-mounted band 5100 may be connected to the display device storage case 5200. The head-mounted band 5100 may include a horizontal band and/or a vertical band for fixing the head-mounted display device 5000 to a user's head. The horizontal band may be configured to surround a side of a user's head, and the vertical band may be configured to surround an upper part of the user's head. However, embodiments are not limited thereto. For example, the head-mounted band 5100 may be implemented in the form of a glasses frame, a helmet, or so on.

The display device storage case 5200 may accommodate the display system 1000 and/or the display device 1200.

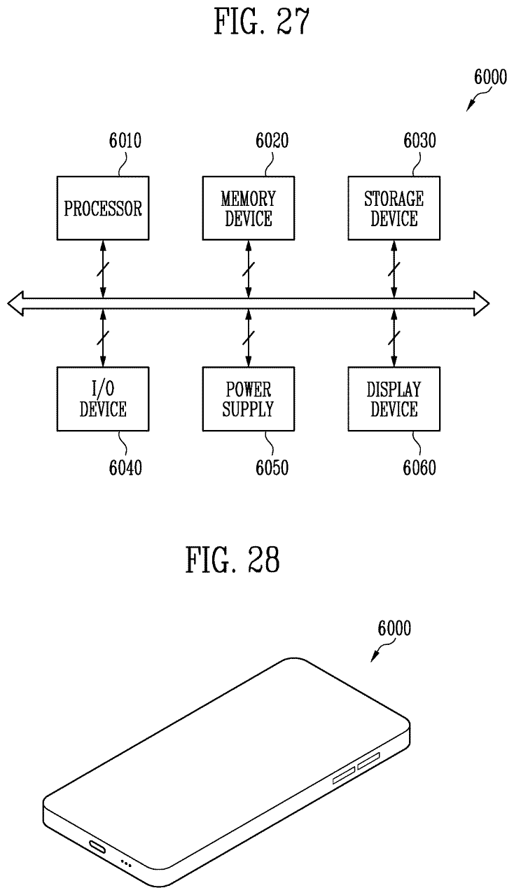

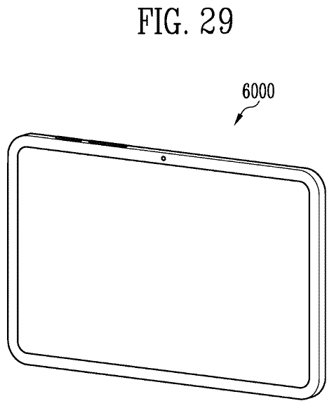

FIG. 27 is a schematic block diagram illustrating an electronic device 1000 including a display device in accordance with an embodiment. FIG. 28 is a schematic diagram illustrating an example where the electronic device 6000 of FIG. 27 is a smartphone. FIG. 29 is a schematic diagram illustrating an example where the electronic device 6000 of FIG. 27 is a tablet computer.

Referring to FIGS. 27 to 29, the electronic device 6000 may include a processor 6010, a memory device 6020, a storage device 6030, an input/output (I/O) device 6040, a power supply 6050, and a display device 6060. The display device 6060 may be the display device DD of FIG. 1. The electronic device 6000 may further include various ports for communication with a video card, a sound card, a memory card, a USB device, or other systems. In an embodiment, as illustrated in FIG. 28, the electronic device 6000 may be a smartphone. In an embodiment, as illustrated in FIG. 29, the electronic device 6000 may be a tablet computer. However, the aforementioned examples are illustrative, and the electronic device 6000 is not necessarily limited to the aforementioned examples. For example, the electronic device 6000 may be a cellular phone, a video phone, a smart pad, a smartwatch, a navigation device for vehicles, a computer monitor, a laptop computer, a head-mounted display device, or the like.

The processor 6010 may perform specific calculations or tasks. In an embodiment, the processor 6010 may be a microprocessor, a central processing unit, an application processor, or the like. The processor 6010 may be connected to other components through an address bus, a control bus, a data bus, and the like. In an embodiment, the processor 6010 may be connected to an expansion bus such as a peripheral component interconnect (PCI) bus. In an embodiment, the processor 6010 may provide input image data to the display device 6060. Hence, the display device 6060 may display an image based on the input image data provided from the processor 6010.

The memory device 6020 may store data needed to perform the operation of the electronic device 6000. The memory device 6020 may function as a working memory and/or a buffer memory for the processor 6010. For example, the memory device 6020 may include one or more volatile memory devices such as a dynamic random access memory (DRAM) device, a static random access memory (SRAM) device, and a mobile DRAM device.

The storage device 6030 may store data in response to control signals or data from the processor 6010. The storage device 6030 may include one or more non-volatile storages to retain the data even when the electronic device 6000 is powered off. In some embodiments, the storage device 6030 may include a solid state drive (SSD), a hard disk drive (HDD), a CD-ROM, or the like.

The I/O device 6040 may include input devices such as a keyboard, a keypad, a touchpad, a touch screen, and a mouse, and output devices such as a speaker and a printer. In an embodiment, the display device 6060 may be integrated with the I/O device 6040.

The power supply 6050 may supply power needed to perform the operation of the electronic device 6000. For example, the power supply 6050 may include a power management integrated circuit (PMIC). In an embodiment, the power supply 6050 may supply power to the display device 6060.

The display device 6060 may display images in response to control signals or data from the processor 6010. The display device 6060 may be connected to other components through the buses or other communication links.

Although specific embodiments and applications are described herein, other embodiments and modifications may be derived from the descriptions given above. Accordingly, the idea of the present disclosure is not limited to the embodiments but extends to the claims set forth below, various obvious modifications, and equivalents.

What is claimed is:

1. A display device comprising:
a substrate;
a pixel circuit layer disposed on the substrate;
a first electrode formed on the pixel circuit layer;
a second electrode formed on the pixel circuit layer and spaced apart from the first electrode; and
a light emitting element connected to the first electrode and the second electrode through a conductive material,
wherein an overflow prevention pattern formed on at least one of the first electrode and the second electrode is configured to prevent an overflow of the conductive material or control a direction of the overflow of the conductive material.

2. The display device of claim 1, wherein the overflow prevention pattern is engraved on one or more of the first electrode and the second electrode.

3. The display device of claim 1, wherein the overflow prevention pattern comprises at least one polygonal pattern.

4. The display device of claim 1, wherein the overflow prevention pattern comprises at least one of an elliptical pattern and a circular pattern.

5. The display device of claim 1, wherein:
the overflow prevention pattern comprises a plurality of stripe-shaped patterns formed on the first electrode and extending in a first direction, and
the plurality of stripe-shaped patterns are repeatedly disposed in a second direction perpendicular to the first direction.

6. The display device of claim 5, wherein each of the plurality of stripe-shaped patterns has a predetermined depth.

7. The display device of claim 1, wherein:
the overflow prevention pattern comprises a plurality of stripe-shaped patterns repeatedly disposed on the first electrode, in a first direction, and
the plurality of stripe-shaped patterns extend in a second direction perpendicular to the first direction.

8. The display device of claim 7, wherein each of the plurality of stripe-shaped patterns comprises a stepped portion comprising a plurality of bottom surfaces, wherein the plurality of bottom surfaces are disposed in the second direction and have different respective depths.

9. The display device of claim 8, wherein for each of the plurality of stripe-shaped patterns, the respective depths of the plurality of bottom surfaces increase in a direction away from the second electrode.

10. The display device of claim 1, wherein:
the overflow prevention pattern comprises a plurality of trapezoidal patterns repeatedly disposed on the first electrode, in a first direction, and
the plurality of trapezoidal patterns extend in a second direction perpendicular to the first direction.

11. The display device of claim 10, wherein widths of the plurality of trapezoidal patterns increase in a direction away from the second electrode.

12. The display device of claim 1, wherein:
the overflow prevention pattern comprises a plurality of wave-shaped patterns formed on the first electrode and extending in a first direction, and
the plurality of wave-shaped patterns are repeatedly disposed in a second direction perpendicular to the first direction.

13. A method of manufacturing a display device, the method comprising:
forming a first electrode and a second electrode on a pixel circuit layer;
connecting a light emitting element to the first electrode and the second electrode;
performing a test operation on the light emitting element; and
removing the light emitting element based on determining, at least in part from performing the test operation, a defect has occurred in the light emitting element.

14. The method of claim 13, further comprising:
forming an overflow prevention pattern on at least one of the first electrode and the second electrode, wherein the overflow prevention pattern is configured to prevent an overflow of a conductive material or control a direction of the overflow of the conductive material;
disposing the conductive material on the first electrode and the second electrode; and
connecting a replacement light emitting element to the first electrode and the second electrode through the conductive material.

15. The method of claim 14, wherein the disposing of the conductive material on the first electrode and the second electrode comprises spraying the conductive material onto the first electrode and the second electrode by using an inkjet method.

16. The method of claim 13, wherein the forming the first electrode and the second electrode comprises forming, in a defective area, the first electrode and the second electrode comprising an overflow prevention pattern for preventing a conductive material from overflowing.

17. The method of claim 16, further comprising:
disposing the conductive material on the first electrode and the second electrode; and
connecting a replacement light emitting element to the first electrode and the second electrode through the conductive material.

18. The method of claim 17, wherein the disposing of the conductive material on the first electrode and the second electrode comprises spraying the conductive material onto the first electrode and the second electrode by using an inkjet method.

19. An electronic device, comprising:
a processor to provide input image data; and
a display device to display an image based on the input image data, wherein the display device comprises:
a substrate;
a pixel circuit layer disposed on the substrate;
a first electrode formed on the pixel circuit layer;
a second electrode formed on the pixel circuit layer and spaced apart from the first electrode; and
a light emitting element connected to the first electrode and the second electrode through a conductive material,
wherein an overflow prevention pattern formed on at least one of the first electrode and the second electrode is configured to prevent an overflow of the conductive material or control a direction of the overflow of the conductive material.

20. The electronic device claim 19, wherein the overflow prevention pattern is engraved on one or more of the first electrode and the second electrode.
